(19) United States
(12) Patent Application Publication
(10) Pub. No.: US 2025/0160012 A1
(43) Pub. Date: May 15, 2025

(54) SEMICONDUCTOR DEVICE, ELECTRONIC DEVICE, AND MANUFACTURING METHOD FOR SEMICONDUCTOR DEVICE

(71) Applicant: SONY SEMICONDUCTOR SOLUTIONS CORPORATION, KANAGAWA (JP)

(72) Inventors: SHINGO HAMAGUCHI, KANAGAWA (JP); MITSUHITO KANATAKE, KANAGAWA (JP)

(21) Appl. No.: 18/837,968

(22) PCT Filed: Feb. 10, 2023
(86) PCT No.: PCT/JP2023/004508

§ 371 Date: Aug. 13, 2024

(30) Foreign Application Priority Data
Feb. 22, 2022 (JP) 2022-026128

(51) Int. Cl. H10F 39/00; H10F 39/15; H10F 39/18

(52) U.S. Cl. CPC H10F 39/804; H10F 39/014; H10F 39/8057; H10F 39/811; H10F 39/15; H10F 39/18

(57) ABSTRACT

A semiconductor device miniaturizes a semiconductor element and reduces manufacturing cost, and eliminates a failure caused by detachment at an interface between resins.

A semiconductor device includes: a substrate; a semiconductor element that is provided on the substrate; a connection member that electrically connects the substrate and the semiconductor element; a transparent member that is provided on an opposite side to a side of the substrate with respect to the semiconductor element; and a sealing resin portion that supports the transparent member with respect to the substrate, seals surroundings between the substrate and the transparent member, and forms a cavity between the semiconductor element and the transparent member together with the semiconductor element and the transparent member, and the semiconductor element includes, on a front side, a resin restriction portion that restricts intrusion of a resin material for forming the sealing resin portion into an inside of the semiconductor element.

### TECHNICAL FIELD

The present disclosure relates to a semiconductor device, an electronic device, and a manufacturing method for the semiconductor device.

### BACKGROUND ART

Conventionally, some semiconductor devices that each include a semiconductor element (semiconductor chip) that is an imaging element such as a CMOS image sensor or a light emitting element such as a semiconductor laser have a following package structure. That is, the package structure is a hollow package structure that supports a glass that is a transparent member with a rib portion made of a resin interposed therebetween on an upper side (front side) of the semiconductor chip mounted on a substrate, and is provided with a sealing resin portion around the semiconductor chip and the glass on the substrate (see, for example, PTL 1).

In such a package structure, the rib portion is a portion at which the glass is adhered to the semiconductor chip, and prevents a sealing resin formed by being applied by a dispenser or the like from wetting and spreading inside the semiconductor chip. The rib portion is formed along the surroundings of the glass, and forms a hollow portion between the semiconductor chip and the glass.

Furthermore, some semiconductor devices include a plurality of wires (bonding wires) that electrically connect the semiconductor chip to the substrate in the above package structure. The wires are formed by covering the entire wires with a sealing resin, or formed by disposing the rib portion above connection portions of the wires with respect to the semiconductor chip to miniaturize the package. Examples of semiconductor devices that adopt the package structure of such a configuration include a Ball Grid Array (BGA) package for an image sensor that includes a plurality of solder balls in a lattice point pattern as external connection terminals on a back side of a substrate.

### CITATION LIST

### Patent Literature

[PTL 1]

JP 2009-88510A

### SUMMARY

### Technical Problem

The above package structure has the following problem. The configuration is provided with the rib portion that supports the glass on the semiconductor chip, and therefore an area for disposing the rib portion on the front side of the semiconductor chip is required. This may become a factor that prevents miniaturization of the semiconductor chip. Furthermore, a material and a process for forming the rib portion are required, and therefore manufacturing cost increases accordingly.

Furthermore, two types of resin materials of the rib portion and the sealing resin are used, and therefore there are interfaces between the respectively different resin materials in the configuration where the surroundings of the rib portion are covered with the sealing resin. Detachment between resins may occur at the interface between the rib portion and the sealing resin.

Detachment at the interface between the rib portion and the sealing resin may become causes of cracking of the semiconductor chip starting from a detachment portion or disconnection of the wires. Furthermore, the detachment portion of the interface between the rib portion and the sealing resin may form an air layer. The air layer becomes a portion that reflects light, and therefore in a case where the semiconductor chip is an imaging element, the reflected light from the air layer may become a cause that produces a flare when the reflected light enters the imaging element.

An object of the present technology is to provide a semiconductor device, an electronic device, and a manufacturing method for the semiconductor device that can miniaturize a semiconductor element and reduce manufacturing cost, and eliminate a failure caused by detachment at an interface between resins.

### Solution to Problem

A semiconductor device according to the present technology includes: a substrate; a semiconductor element that is provided on the substrate; a connection member that electrically connects the substrate and the semiconductor element; a transparent member that is provided on an opposite side to a side of the substrate with respect to the semiconductor element; and a sealing resin portion that supports the transparent member with respect to the substrate, seals surroundings between the substrate and the transparent member, and forms a cavity between the semiconductor element and the transparent member together with the semiconductor element and the transparent member, and the semiconductor element includes, on a front side, a resin restriction portion that restricts intrusion of a resin material for forming the sealing resin portion into an inside of the semiconductor element.

According to another aspect of the semiconductor device according to the present technology, in the semiconductor device, the resin restriction portion is one or a plurality of groove portions that are formed on the front side of the semiconductor element.

According to another aspect of the semiconductor device according to the present technology, in the semiconductor device, the transparent member is a plate-like member whose one plate surface faces the semiconductor element, and has most of a portion on an upper side of a side surface as an exposed surface portion that is not covered with the sealing resin portion.

According to another aspect of the semiconductor device according to the present technology, in the semiconductor device, the transparent member includes at least one of one or a plurality of groove portions and ridge portions on a surface on a side facing the semiconductor element, the groove portions and the ridge portions restricting the intrusion of the resin material for forming the sealing resin portion into the inside of the transparent member.

According to another aspect of the semiconductor device according to the present technology, in the semiconductor device, the transparent member includes a groove portion on a surface on a side facing the semiconductor element, the connection member is a wire whose upper side is disposed as a protrusion side such that an upper end is located at a position higher than a front surface of the semiconductor element, and the groove portion is formed in a region including at least part of a portion of the connection member existing at the position higher than the front surface of the semiconductor element in plan view.

According to another aspect of the semiconductor device according to the present technology, the semiconductor device further includes a resin film portion that is provided on a surface of the transparent member on a side facing the semiconductor element, and restricts the intrusion of the resin material for forming the sealing resin portion into the inside of the transparent member.

According to another aspect of the semiconductor device according to the present technology, in the semiconductor device, the resin film portion is formed as a light-blocking film.

According to another aspect of the semiconductor device according to the present technology, in the semiconductor device, the semiconductor element includes a step portion as the resin restriction portion on the front side, the step portion forming a step formed at a periphery portion of the semiconductor element and on a side lower than an other portion of the semiconductor element, and forming a step surface that accepts connection of the connection member and is covered with the sealing resin portion.

A semiconductor device according to the present technology includes: a substrate; a semiconductor element that is provided on the substrate; a connection member that electrically connects the substrate and the semiconductor element; a transparent member that is provided on an opposite side to a side of the substrate with respect to the semiconductor element; and a sealing resin portion that supports the transparent member with respect to the substrate, seals surroundings between the substrate and the transparent member, and forms a cavity between the semiconductor element and the transparent member together with the semiconductor element and the transparent member, and the sealing resin portion covers a side surface of the semiconductor element and a connection portion of the connection member with respect to the substrate, and exposes an entire front side of the semiconductor element that accepts connection of one end side of the connection member.

According to another aspect of the semiconductor device according to the present technology, the semiconductor device further includes a light-blocking film portion that is provided on a surface on a side of the transparent member facing the semiconductor element, covers an upper side of the connection portion of at least the connection member with respect to the semiconductor element, and restricts the intrusion of the resin material for forming the sealing resin portion into the inside of the transparent member.

According to another aspect of the semiconductor device according to the present technology, in the semiconductor device, the transparent member includes a protrusion portion on a side facing the semiconductor element, the protrusion portion forming a second surface portion located on a side of the semiconductor element with respect to a first surface portion covered with the sealing resin portion.

According to another aspect of the semiconductor device according to the present technology, in the semiconductor device, the transparent member includes a peripheral wall portion that forms a contact portion with respect to the sealing resin portion in a region on an outer side of the semiconductor element in plan view.

An electronic device according to the present technology includes a semiconductor device that includes: a substrate; a semiconductor element that is provided on the substrate; a connection member that electrically connects the substrate and the semiconductor element; a transparent member that is provided on an opposite side to a side of the substrate with respect to the semiconductor element; and a sealing resin portion that supports the transparent member with respect to the substrate, seals surroundings between the substrate and the transparent member, and forms a cavity between the semiconductor element and the transparent member together with the semiconductor element and the transparent member, and the semiconductor element includes, on a front side, a resin restriction portion that restricts intrusion of a resin material for forming the sealing resin portion into an inside of the semiconductor element.

An electronic device according to the present technology includes a semiconductor device that includes: a substrate; a semiconductor element that is provided on the substrate; a connection member that electrically connects the substrate and the semiconductor element; a transparent member that is provided on an opposite side to a side of the substrate with respect to the semiconductor element; and a sealing resin portion that supports the transparent member with respect to the substrate, seals surroundings between the substrate and the transparent member, and forms a cavity between the semiconductor element and the transparent member together with the semiconductor element and the transparent member, and the sealing resin portion covers a side surface of the semiconductor element and a connection portion of the connection member with respect to the substrate, and exposes an entire front side of the semiconductor element that accepts connection of one end side of the connection member.

A manufacturing method for a semiconductor device according to the present technology includes: providing a semiconductor element on a substrate; providing a connection member that electrically connects the substrate and the semiconductor element; applying a sealing resin material around the semiconductor element on the substrate so as to cover at least a side surface of the semiconductor element and a connection portion of the connection member with respect to the substrate; mounting, on the sealing resin material, a transparent member located above the semiconductor element; and curing the sealing resin material.

### BRIEF DESCRIPTION OF DRAWINGS

FIG. 1 is a side cross-sectional view illustrating a configuration of a solid-state imaging device according to a first embodiment of the present technology.

FIG. 2 is a partially enlarged side cross-sectional view illustrating the configuration of the solid-state imaging device according to the first embodiment of the present technology.

FIG. 3 is an explanatory drawing illustrating a manufacturing method for the solid-state imaging device according to the first embodiment of the present technology.

FIG. 4 is an explanatory drawing illustrating the manufacturing method for the solid-state imaging device according to the first embodiment of the present technology.

FIG. 5 is a side cross-sectional view illustrating a configuration example of a conventional solid-state imaging device.

FIG. 6 is a partial side cross-sectional view illustrating the configuration of a first modification example of the solid-state imaging device according to the first embodiment of the present technology.

FIG. 7 is a partial side cross-sectional view illustrating the configuration of a second modification example of the solid-state imaging device according to the first embodiment of the present technology.

FIG. 8 is a partial side cross-sectional view illustrating the configuration of a third modification example of the solid-state imaging device according to the first embodiment of the present technology.

FIG. 9 is a side cross-sectional view illustrating the configuration of a fourth modification example of the solid-state imaging device according to the first embodiment of the present technology.

FIG. 10 is a side cross-sectional view illustrating the configuration of the solid-state imaging device according to a second embodiment of the present technology.

FIG. 11 is a partially enlarged side cross-sectional view illustrating a configuration of the solid-state imaging device according to the second embodiment of the present technology.

FIG. 12 is a partial side cross-sectional view illustrating the configuration of a modification example of the solid-state imaging device according to the second embodiment of the present technology.

FIG. 13 is a side cross-sectional view illustrating a configuration of the solid-state imaging device according to a third embodiment of the present technology.

FIG. 14 is a partial side cross-sectional view illustrating the configuration of a first modification example of the solid-state imaging device according to the third embodiment of the present technology.

FIG. 15 is a partial side cross-sectional view illustrating the configuration of a second modification example of the solid-state imaging device according to the third embodiment of the present technology.

FIG. 16 is a side cross-sectional view illustrating a configuration of the solid-state imaging device according to a fourth embodiment of the present technology.

FIG. 17 is an explanatory drawing illustrating a manufacturing method for the solid-state imaging device according to the fourth embodiment of the present technology.

FIG. 18 is a side cross-sectional view illustrating a configuration of the solid-state imaging device according to a fifth embodiment of the present technology.

FIG. 19 is a side cross-sectional view illustrating a configuration of the solid-state imaging device according to a sixth embodiment of the present technology.

FIG. 20 is a side cross-sectional view illustrating a configuration of the solid-state imaging device according to a seventh embodiment of the present technology.

FIG. 21 is an explanatory drawing illustrating a manufacturing method for the solid-state imaging device according to the seventh embodiment of the present technology.

FIG. 22 is a side cross-sectional view illustrating the configuration of a modification example of the solid-state imaging device according to the seventh embodiment of the present technology.

FIG. 23 is a block diagram illustrating a configuration example of an electronic device including the solid-state imaging device according to the embodiments of the present technology.

### DESCRIPTION OF EMBODIMENTS

The present technology proposes a semiconductor hollow package structure that seals the surroundings of a semiconductor element using one type of a resin material, and supports a transparent member provided above the semiconductor element in a configuration where a substrate and the semiconductor element provided on the substrate are electrically connected by a connection member. The present technology miniaturizes the semiconductor element and reduces manufacturing cost by such a package structure, removes an interface between resins, and solves a failure caused by detachment of the interface between the resins.

Modes for carrying out the present technology (hereinafter referred to as embodiments) will be described below with reference to the drawings. The following embodiments will describe citing an example an imaging device (solid-state imaging device) including a solid-state imaging element that is an example of a semiconductor element as a semiconductor device. The description of the embodiments will be made in the following order.

1. Configuration example of solid-state imaging device according to first embodiment

2. Manufacturing method for solid-state imaging device according to first embodiment

3. Modification example of solid-state imaging device according to first embodiment

4. Configuration example of solid-state imaging device according to second embodiment

5. Modification example of solid-state imaging device according to second embodiment

6. Configuration example of solid-state imaging device according to third embodiment

7. Modification example of solid-state imaging device according to third embodiment

8. Configuration example of solid-state imaging device according to fourth embodiment

9. Manufacturing method for solid-state imaging device according to fourth embodiment

10. Configuration example of solid-state imaging device according to fifth embodiment

11. Configuration example of solid-state imaging device according to sixth embodiment

12. Configuration example of solid-state imaging device according to seventh embodiment

13. Manufacturing method for solid-state imaging device according to seventh embodiment

14. Modification example of solid-state imaging device according to seventh embodiment

15. Configuration example of electronic device

### 1. Configuration Example of Solid-State Imaging Device According to First Embodiment

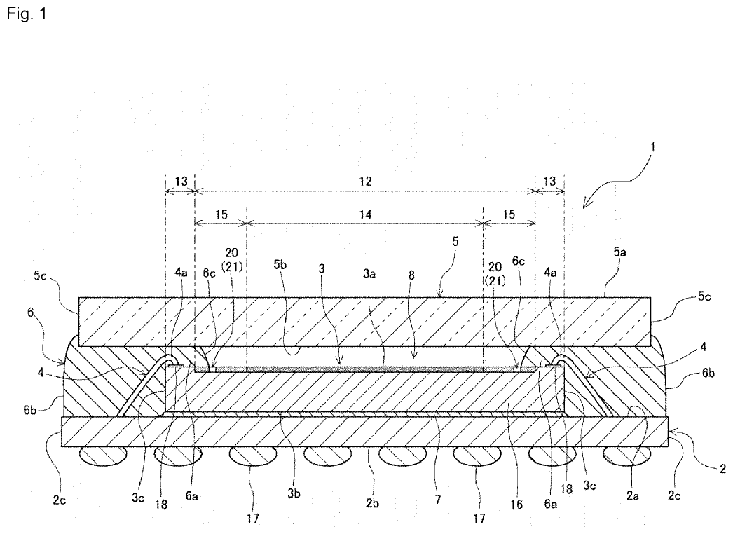

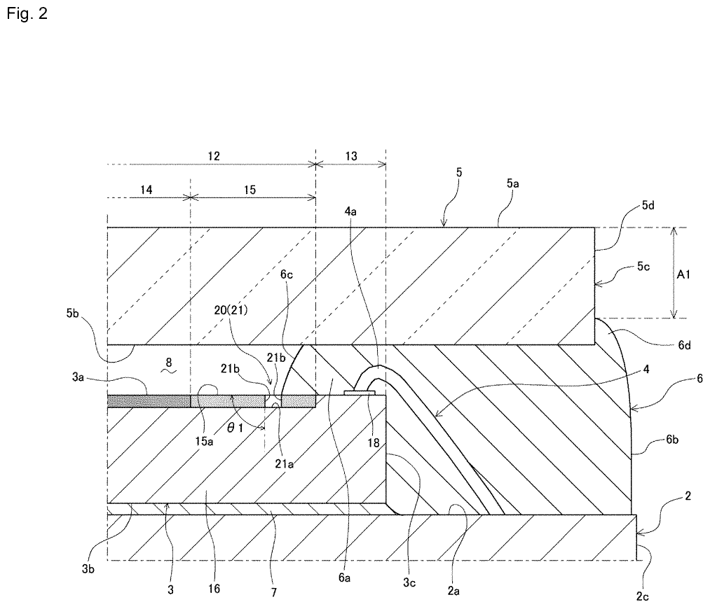

Referring to FIGS. 1 and 2, a configuration example of a solid-state imaging device according to a first embodiment of the present technology will be described. Note that the vertical direction in FIG. 1 is the vertical direction of a solid-state imaging device 1.

As illustrated in FIGS. 1 and 2, the solid-state imaging device 1 includes a substrate 2, an image sensor 3 that is a solid-state imaging element provided on the substrate 2, and wires (bonding wires) 4 that are a plurality of connection members. Furthermore, the solid-state imaging device 1 includes a glass 5 that is a transparent member provided above the image sensor 3, and a sealing resin portion 6 that is formed at a periphery portion of the solid-state imaging device 1.

The substrate 2 is an organic substrate whose base material is an organic material such as a glass epoxy resin that is the one type of a fiber reinforced plastic, and is a circuit board on which a predetermined circuit pattern made of a metal material has been formed. In this regard, the substrate 2 may be another type of a substrate such as a ceramic substrate formed using, as a base material, ceramics such as alumina (Al₂O₃), aluminum nitride (AlN), or silicon nitride (Si₃N₄).

The substrate 2 is a member of a flat plate shape having the outer shape of a rectangular plate shape. The substrate 2 includes a front surface 2a that is one plate surface on which the image sensor 3 is mounted, a back surface 2b that is a plate surface (other plate surface) on an opposite side thereof, and four side surfaces 2c. The image sensor 3 is die-bonded to a front surface 2a side of the substrate 2. The image sensor 3 is adhered to the front surface 2a of the substrate 2 by a die-bonding material 7 made of an insulating or conductive adhesive.

The image sensor 3 is a semiconductor element that includes a semiconductor substrate 16 made of silicon (Si) that is an example of a semiconductor. The image sensor 3 is a chip of a rectangular plate shape, and has a front surface 3a side that is one plate surface as a light receiving surface side, and the (other) plate surface on the opposite side thereof as a back surface 3b. The image sensor 3 has four side surfaces 3c.

A plurality of light receiving elements (photoelectric conversion elements) are formed on the front surface 3a side of the image sensor 3. The image sensor 3 is a Complementary Metal Oxide Semiconductor (CMOS) image sensor. In this regard, the image sensor 3 may be another imaging element such as a Charge Coupled Device (CCD) image sensor.

The image sensor 3 includes, on the front surface 3a side, a pixel region 12 that is a light receiving region in which multiple pixels have been formed, and a peripheral region 13 that is a region around the pixel region 12. In the pixel region 12, multiple pixels are formed in a predetermined array such as a Bayer array, and constitutes a light receiving unit in the image sensor 3.

The pixel region 12 includes an effective pixel region 14 in which a signal charge is generated, amplified, and read by photoelectric conversion in each pixel, and a peripheral circuit region 15 that is a region around the effective pixel region 14 and is formed by a layer such as an organic film.

Pixels of the effective pixel region 14 each include a photodiode as a photoelectric conversion unit having a photoelectric conversion function, and a plurality of pixel transistors. The photodiodes are formed in a semiconductor substrate 16. In the peripheral circuit region 15, a predetermined peripheral circuit such as a signal processing circuit that performs predetermined processing on a signal supplied in units of pixels from the effective pixel region 14 is formed. Signals processed by the signal processing circuit are output via the wires 4.

A color filter and an on-chip lens are formed so as to meet each pixel of the effective pixel region 14 on the front surface 3a side of the image sensor 3 and with an anti-reflective film made of an oxide film or the like, a flattened film formed using, for example, an organic material, or the like interposed therebetween on the semiconductor substrate. Light having entered the on-chip lens is received by the photodiodes through the color filter, the flattened film, or the like. Note that the configuration of the image sensor 3 according to the present technology is not limited in particular.

Examples of the configuration of the image sensor 3 include a front side illumination type in which the pixel region 12 is formed on the front side of the semiconductor substrate, a back side illumination type in which photodiodes or the like are reversely disposed to improve the transmittance of light and the back side of the semiconductor substrate is a light receiving surface side, and the like.

The wire 4 is a conductive wire that electrically connects the substrate 2 and the image sensor 3. The wire 4 is a metal thin line made of, for example, Au (gold), Cu (copper), or Al (aluminum).

The wire 4 has the one end side that is connected to an electrode (not illustrated) of a lead terminal or the like formed on the front surface 2a of the substrate 2, and the other end side that is connected to pad electrodes 18 formed on the front surface 3a of the image sensor 3, and electrically connect these electrodes. The plurality of wires 4 are provided so as to correspond to the number of the pad electrodes 18.

The pad electrodes 18 of the image sensor 3 are terminals for transmitting and receiving signals to and from an outside of the image sensor 3, and are formed with an aluminum material or the like using a method such as plating or spattering. The plurality of pad electrodes 18 are formed in a predetermined array in the peripheral region 13 on the front surface 3a of the image sensor 3.

The wire 4 has a curved shape or a bent shape such as an arch shape that protrudes toward an upper side, and is wired across the front surface 3a of the image sensor 3 and the front surface 2a of the substrate 2. In the present embodiment, the wire 4 has a shape that rises from the connection portion with respect to the front surface 3a of the image sensor 3 to form a top portion 4a that protrudes toward the upper side, and smoothly goes down toward the connection portion with respect to the front surface 2a of the substrate 2. As described above, the wire 4 is arranged with the upper side serving as the protrusion side such that the top portion 4a that is the upper end is located at a position higher than the front surface 3a of the image sensor 3.

The plurality of electrodes on the front surface 2a of the substrate 2 that accepts connection of the one end sides of the wires 4 are electrically connected to a plurality of terminal electrodes formed on a back surface 2b side of the substrate 2 with a predetermined wiring portion formed in the substrate 2 interposed therebetween. Each terminal electrode is provided with a solder ball 17.

The solder ball 17 is formed and two-dimensionally arranged in a lattice point pattern along the rectangular outer shape of the image sensor 3 to form a Ball Grid Array (BGA). The solder ball 17 is a terminal that makes electrical connection to a set substrate that is a circuit board on which the solid-state imaging device 1 is mounted in the electronic device on which the solid-state imaging device 1 is mounted.

The glass 5 is an example of a transparent member, and is provided on an opposite side (upper side) to a substrate 2 side with respect to the image sensor 3. The glass 5 has an outer shape of a rectangular plate shape. The glass 5 includes a front surface 5a that is a plate surface on the upper side, a back surface 5b that is a plate surface on the opposite side thereto and faces the image sensor 3, and four side surfaces 5c. Thus, the glass 5 is provided as a plate-like member whose back surface 5b that is the one plate surface faces the image sensor 3.

The glass 5 is provided on the light receiving surface side of the image sensor 3 and in parallel and at a predetermined interval with respect to the image sensor 3. The glass 5 is supported by the sealing resin portion 6 in a state where the glass 5 is fixed to the substrate 2 and the image sensor 3, and is located above the image sensor 3. The glass 5 has a larger outer shape dimension than that of the image sensor 3, and is provided such that the entire image sensor 3 is located within a range of the outer shape in plan view. Furthermore, the glass 5 has a smaller outer shape dimension that is one size larger than that of the substrate 2 in plan view, and is provided such that the four side surfaces 5c are located on the inner side of the four side surfaces 2c of the substrate 2.

The glass 5 allows transmission of various light entering from a front surface 5a side through an optical system such as a lens located above the glass 5. The light having transmitted through the glass 5 reaches the light receiving surface of the image sensor 3. The glass 5 has a function of protecting a light receiving surface side of the image sensor 3. Note that, for example, a plastic plate or a silicon plate can be used as the transparent member according to the present technology instead of the glass 5.

The sealing resin portion 6 is a portion that supports the glass 5 with respect to the substrate 2. The sealing resin portion 6 seals the surroundings between the substrate 2 and the glass 5, and forms a cavity 8 that is a sealed space between the image sensor 3 and the glass 5 together with the image sensor 3 and the glass 5.

The sealing resin portion 6 serves as a portion that supports the glass 5 with respect to the substrate 2 and the image sensor 3, and supports the glass 5 at a position above the wires 4. That is, the sealing resin portion 6 has in a substantially entire planar view outer shape a portion that supports the glass 5 such that the back surface 5b of the glass 5 is located above the top portions 4a of the wires 4, and is located between the top portions 4a of the wires 4 and the back surface 5b of the glass 5 in the vertical direction.

The sealing resin portion 6 is provided around the image sensor 3 on the substrate 2, and covers and seals the entire circumference of the surroundings of the image sensor 3 between the substrate 2 and the glass 5. Hence, the sealing resin portion 6 is formed in a frame shape along the rectangular outer shape of the substrate 2 in plan view.

The sealing resin portion 6 includes most of the portion interposed between the substrate 2 and the glass 5, and includes an inner portion as an on-chip interposed portion 6a that is interposed between the image sensor 3 and the glass 5.

Furthermore, the sealing resin portion 6 includes, on the outer circumferential side, an outer side surface 6b that substantially continues to the four side surfaces 2c of the substrate 2.

The sealing resin portion 6 is a resin portion that covers the wires 4 and the connection portions of the wires 4 with respect to the substrate 2 and the image sensor 3. The sealing resin portion 6 covers a periphery portion of the front surface 2a of the substrate 2, a periphery portion of the front surface 3a and the entire side surfaces 3c of the image sensor 3, and a periphery portion of the back surface 5b of the glass 5 in a state where the entire wires 4 are buried.

The on-chip interposed portion 6a of the sealing resin portion 6 is a portion that forms the cavity 8 together with the image sensor 3 and the glass 5. More specifically, the cavity 8 is a space in which the front surface 3a of the image sensor 3, the back surface 5b of the glass 5, and an inner side surface 6c of the on-chip interposed portion 6a face each other. The inner side surface 6c of the sealing resin portion 6 is a cavity formation surface. The sealing resin portion 6 seals the surroundings of the cavity 8 airtight, and blocks intrusion of moisture (water vapor), dust, and the like into the cavity 8 from the outside.

The on-chip interposed portion 6a in the sealing resin portion 6 is formed at the entire circumference of the periphery portion of the front surface 3a of the image sensor 3. Accordingly, the on-chip interposed portion 6a is formed in, for example, the frame shape along the planar view outer shape of the image sensor 3. The sealing resin portion 6 has a lower portion on an inner circumferential side that is in contact with the side surfaces 3c of the image sensor 3, and an upper portion on the inner circumferential side as the on-chip interposed portion 6a.

The sealing resin portion 6 is formed by curing a resin material around the image sensor 3 on the substrate 2 in the configuration where the image sensor 3 is mounted on the substrate 2 and the substrate 2 and the image sensor 3 are connected by the wires 4. The sealing resin portion 6 is formed by, for example, the potting process that uses a dispenser.

The material of the sealing resin portion 6 is a resin whose main component is a silicon oxide, or a thermosetting resin containing a filler such as alumina. As the resin material for forming the sealing resin portion 6, for example, thermosetting resins such as a phenol-based resin, a silicone-based resin, an acrylic-based resin, an epoxy-based resin, an urethane-based resin, a silicon resin, and a polyetherimide-based resin, thermoplastic resins such as polyamideimide, polypropylene, and liquid crystal polymer, a photosensitive resin such as an UltraViolet (UV) curing resin that is an acrylic-based resin, a rubber, and other known resin materials are used alone or by combining a plurality of resin materials. Note that the sealing resin portion 6 has the insulation property.

Furthermore, a material that has a light-blocking property can be used as the material of the sealing resin portion 6. More specifically, as the material of the sealing resin portion 6, a black resin material containing a black pigment such as carbon black or titanium black is used. Consequently, the sealing resin portion 6 becomes a black portion, so that it is possible to cause the sealing resin portion 6 to function as a light-blacking portion.

As described above, the solid-state imaging device 1 has the hollow package structure that the glass 5 is supported on the substrate 2 and the image sensor 3 mounted on the substrate 2 and with the sealing resin portion 6 that functions as the sealing portion interposed therebetween, and the cavity 8 is formed between the image sensor 3 and the glass 5.

In the solid-state imaging device 1 employing the above configuration, the image sensor 3 includes, on the front surface 3a side, a resin restriction portion 20 that restricts intrusion of the resin material (hereinafter, referred to as a “sealing resin material”) for forming the sealing resin portion 6 into the inside of the image sensor 3. The image sensor 3 includes as the resin restriction portion 20 one groove portion 21 that is formed on the front surface 3a side of the image sensor 3.

The groove portion 21 is formed at a front surface portion of the image sensor 3, and in the peripheral circuit region 15 that is a region on the inner side of the peripheral region 13. The groove portion 21 is an excavated portion in a front surface 15a of the peripheral circuit region 15, and is formed in an endless shape so as to surround the entire circumference of the surroundings of the effective pixel region 14. The groove portion 21 is formed into, for example, a rectangular shape along the outer shape of the image sensor 3 in plan view.

As illustrated in FIG. 2, the groove portion 21 includes a bottom surface portion 21a of a horizontal shape, and left and right side surface portions 21b that face each other, and these surface portions form a groove shape of a substantially “U” shape in a horizontal cross section. That is, the groove portion 21 is formed as a rectangular groove whose upper side is an open side and that has a horizontal cross-sectional shape along the rectangular shape.

The groove portion 21 is formed such that the left and right side surface portions 21b are vertical surfaces. Hence, an angle θ1 formed between the left and right side surface portions 21b, and the front surface 3a of the image sensor 3 at a formation portion of the groove portion 21, that is, the front surface 15a of the peripheral circuit region 15 is approximately 90° in horizontal cross-sectional view. In this regard, a value of the angle θ1 in horizontal cross-sectional view of a corner portion (hereinafter, referred to as “a corner portion of the groove portion 21”) formed between the side surface portions 21b and the front surface 15a is not limited in particular. The angle θ1 is set to a value within a range of, for example, 60 to 90°. Furthermore, the angle θ1 may be an obtuse angle.

The groove portion 21 is formed such that each of the groove width and the groove depth is, for example, approximately several micrometers. This is just an example, and the groove portion 21 is formed such that the groove width is approximately 3 μm and the groove depth is approximately 1 μm. The groove width of the groove portion 21 is the dimension between the left and right side surface portions 21b, and the groove depth of the groove portion 21 is the dimension from the bottom surface portion 21a to the front surface 15a of the peripheral circuit region 15, that is, the dimension in the vertical direction of the side surface portions 21b.

The groove portion 21 can be formed by an excavating process by etching such as dry etching, patterning that uses a photolithography technique, or the like in a process (wafer process) of manufacturing the image sensor 3. For example, dry etching can easily make the angle θ1 of the groove portion 21 close to 90°.

The groove portion 21 is a portion that holds back a flow of the sealing resin material applied as a fluid (liquid) having predetermined viscosity in a process of forming the sealing resin portion 6. That is, the groove portion 21 restricts intrusion of the sealing resin material applied to the outer circumferential side of the image sensor 3 to the inner side (effective pixel region 14 side) beyond the groove portion 21 on the front surface portion of the image sensor 3.

More specifically, in a case where, for example, the angle θ1 is approximately 90°, the groove portion 21 holds back the inflow of the sealing resin material into the groove portion 21 according to a relationship that uses a contact angle of the sealing resin material for a friction force (the tension of an interface between a solid and a liquid) at the corner portion of the groove portion 21, a surface tension of the sealing resin material (the surface tension of the liquid) at the corner portion of the groove portion 21, and a surface tension of the front surface 15a of the peripheral circuit region 15 (the surface tension of the solid). In a case where, for example, the contact angle is 90°, the friction force at the corner portion of the groove portion 21 and the surface tension of the front surface 15a of the peripheral circuit region 15 match, so that the sealing resin material does not flow into the groove portion 21. Here, the contact angle is an angle formed between the front surface 15a of the peripheral circuit region 15 and the sealing resin material at the corner portion of the groove portion 21.

By curing the sealing resin material in a state where the inflow of the sealing resin material to the groove portion 21 is held back, the inner side of the on-chip interposed portion 6a of the sealing resin portion 6 is located at an edge end of the corner portion formed between the side surface portion 21b (the right side surface portion 21b in FIG. 2) on the outer side of the groove portion 21 and the front surface 15a of the peripheral circuit region 15. That is, the sealing resin portion 6 is formed such that the inner side surface 6c of the on-chip interposed portion 6a substantially continues to the side surface portion 21b on the outer side of the groove portion 21.

The inner side surface 6c of the on-chip interposed portion 6a forms a curved line of an arc shape whose inner circumferential side is a protrusion side in lateral cross-sectional view as illustrated in, for example, FIG. 2. As described above, the sealing resin portion 6 has the planar view shape of the edge portion on the inner circumferential side formed by the on-chip interposed portion 6a as a rectangular frame shape along the planar view shape of the groove portion 21.

Note that the groove portion 21 may allow the sealing resin material to flow into the groove as long as the groove portion 21 does not allow the sealing resin material to intrude the inner side beyond the groove portion 21. In this case, the groove portion 21 internally includes part of the sealing resin portion 6 whose sealing resin material has been cured.

Furthermore, as for the relationship between the sealing resin portion 6 and the glass 5, most of the portions on the upper sides of the side surfaces 5c of the glass 5 are exposed surface portions 5d that are not covered with the sealing resin portion 6. As illustrated in FIG. 2, the sealing resin portion 6 includes a glass covering portion 6d that covers little portions on the lower sides of the side surfaces 5c of the glass 5. The side surface 5c of the glass 5 includes as the exposed surface portion 5d a portion on the upper side of the portion covered with the glass covering portion 6d of the sealing resin portion 6. Note that the glass covering portion 6d is formed over the entire circumference of the four side surfaces 5c of the glass 5.

In the example illustrated in FIG. 2, portions in a range of approximately ¼ of the lower sides of the side surfaces 5c in a thickness direction of the glass 5 that is the vertical direction are covered with the glass covering portion 6d. That is, portions (see reference numeral A1) in a range of approximately ¾ of the upper sides of the side surfaces 5c of the glass 5 are the exposed surface portions 5d in an exposed state without being covered with the sealing resin portion 6.

The exposed surface portions 5d of the side surfaces 5c of the glass 5 are portions in a range of at least half or more of the upper sides in the thickness direction of the glass 5. The range in the vertical direction of the exposed surface portions 5d of the side surfaces 5c of the glass 5 is preferably as wide as possible. The sealing resin portion 6 may be formed such that the entire side surfaces 5c of the glass 5 are exposed.

### 2. Manufacturing Method for Solid-State Imaging Device According to First Embodiment

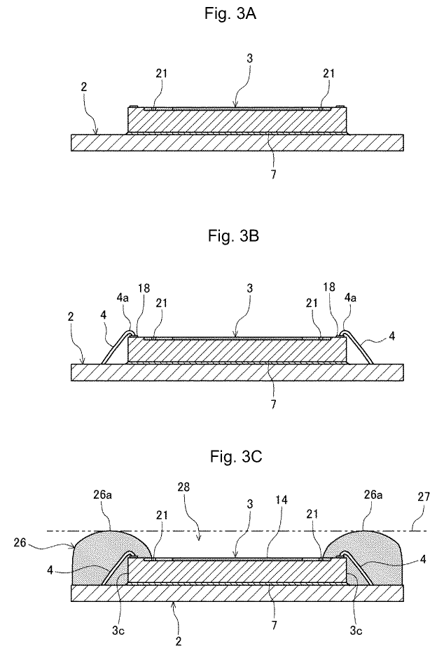

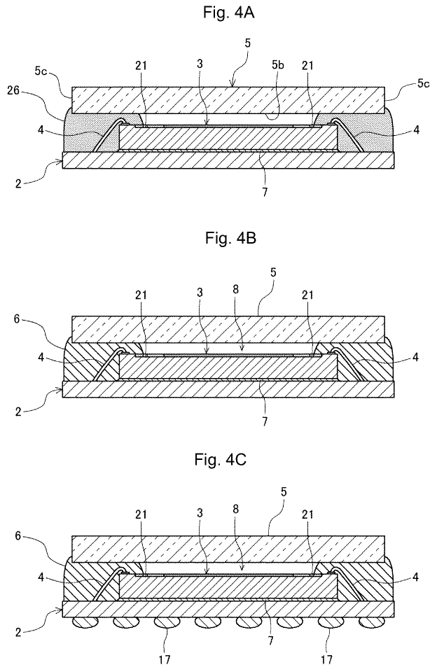

Referring to FIGS. 3 and 4, an example of a manufacturing method for the solid-state imaging device 1 according to the first embodiment of the present technology will be described.

According to the manufacturing method for the solid-state imaging device 1, the substrate 2 and the image sensor 3 including the groove portion 21 are prepared first. Furthermore, a process of providing the image sensor 3 on the substrate 2 as illustrated in FIG. 3A is performed. That is, die bonding of die-bonding the image sensor 3 to the substrate 2 is performed. In this process, as illustrated in FIG. 3A, the image sensor 3 is adhered to a predetermined mounting portion on the front surface 2a of the substrate 2 using the die-bonding material 7.

Next, a process of providing the wires 4 that electrically connect the substrate 2 and the image sensor 3 as illustrated in FIG. 3B is performed. Here, wire bonding of connecting and electrically connecting the electrodes formed on the front surface 2a of the substrate 2 and the pad electrodes 18 formed on the front surface 3a of the image sensor 3 by using the wires 4 is performed. The wires 4 are wired in a predetermined shape that forms the top portions 4a.

Next, a process of applying a sealing resin material 26 for forming the sealing resin portion 6 to the configuration obtained by die bonding and wire bonding as illustrated in FIG. 3C is performed. The sealing resin material 26 is applied by, for example, the potting process that uses a dispenser. In this case, the sealing resin material 26 is applied to a predetermined portion while being dispensed from a nozzle of the dispenser.

The sealing resin material 26 is applied to cover at least the side surfaces 3c of the image sensor 3 and the connection portions of the wires 4 with respect to the substrate 2 around the image sensor 3 on the substrate 2. In the present embodiment, as illustrated in FIG. 3C, the sealing resin material 26 is applied so as to cover the entire wires 4 including the connection portions of the wires 4 with respect to the image sensor 3.

The sealing resin material 26 is applied such that an upper end portion 26a of the sealing resin material 26 is located on the upper side of the top portions 4a of all of the wires 4. Furthermore, the sealing resin material 26 is applied to make the height common across the entire circumference of the surroundings of the image sensor 3. That is, the sealing resin material 26 is applied to locate the height of the upper end portion 26a on a common virtual horizontal plane 27 in a region portion that forms a rectangular frame shape in plan view along the planar view outer shape of the image sensor 3.

In a state where the sealing resin material 26 is applied, the sealing resin material 26 forms on the upper side of the image sensor 3 an opening portion 28 of a substantially rectangular shape in plan view that the entire effective pixel region 14 faces. Note that, as illustrated in FIG. 3C, the sealing resin material 26 forms a curved shape that protrudes toward the upper side in lateral cross-sectional view at an upper end portion in an example of a mode of an applied state of the sealing resin material 26.

In the process of applying the sealing resin material 26, the image sensor 3 includes the groove portion 21 on the front surface 3a, so that the groove portion 21 holds back the flow of the sealing resin material 26. Consequently, intrusion of the sealing resin material 26 toward the effective pixel region 14 is restricted, and the sealing resin material 26 is prevented from contaminating the effective pixel region 14. Note that an application amount of the sealing resin material 26 is controlled as appropriate to restrict the intrusion of the sealing resin material 26 toward the effective pixel region 14.

Next, a process of mounting on the sealing resin material 26 the glass 5 located above the image sensor 3 as illustrated in FIG. 4A is performed. Here, a glass mounting process of mounting the glass 5 on the sealing resin material 26 by a chip mounter or the like is performed.

The glass 5 is mounted on the sealing resin material 26 to close the opening portion 28 formed by the sealing resin material 26 on the upper side of the image sensor 3. The glass 5 mounted on the sealing resin material 26 slightly sinks into the sealing resin material 26 due to the own weight. Consequently, according to the amount, the viscosity, and the like of the sealing resin material 26, the sealing resin material 26 is located on the upper side of the back surface 5b around the glass 5, and the lower end portions of the side surfaces 5C are covered with the sealing resin material 26.

After the glass mounting process, a process of curing the sealing resin material 26 is performed. When the sealing resin material 26 is a thermosetting material, a heating process (curing) of curing the sealing resin material 26 is performed. Furthermore, when the sealing resin material 26 is a UV-curing material, a process of irradiating the sealing resin material 26 with UV light is performed as a process for curing the sealing resin material 26.

When the sealing resin material 26 is cured, the sealing resin portion 6 is formed as illustrated in FIG. 4B. That is, the glass 5 is fixed to and supported by the substrate 2 and the image sensor 3 with the sealing resin portion 6 interposed therebetween, and the cavity 8 that is a sealing space is formed between the image sensor 3 and the glass 5.

Furthermore, a process of forming the plurality of solder balls 17 on the back surface 2b side of the substrate 2 as illustrated in FIG. 4C is performed. Here, a ball mounting process of mounting the solder balls 17 on a plurality of terminal electrodes formed on the back surface 2b side of the substrate 2 is performed.

According to the above manufacturing process, the solid-state imaging device 1 illustrated in FIG. 1 can be obtained.

According to the solid-state imaging device 1 and the manufacturing method therefor according to the above present embodiment, it is possible to miniaturize the image sensor 3 and reduce manufacturing cost, and eliminate a failure caused by detachment at an interface between resins.

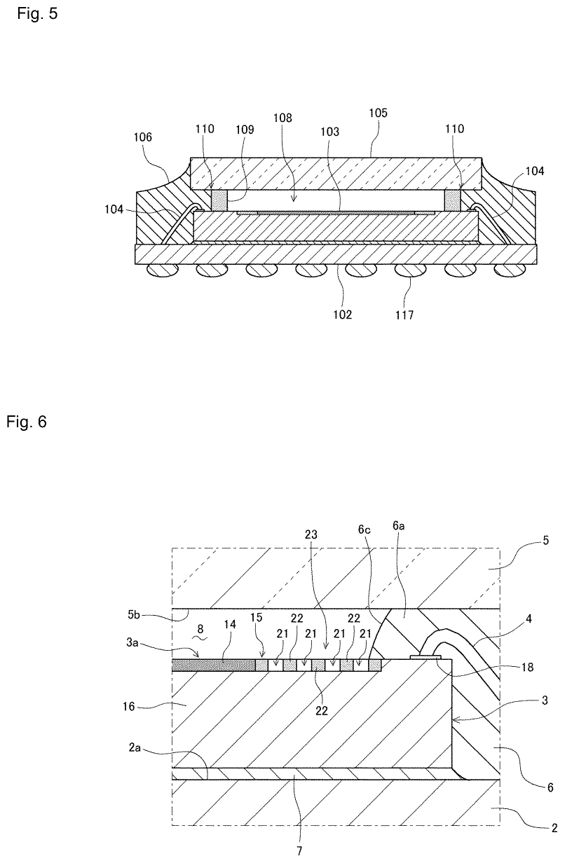

A configuration example of a conventional solid-state imaging device is a hollow package structure that, as illustrated in FIG. 5, a glass 105 is supported on an upper side (front side) of a chip 103 that is an image sensor mounted on a substrate 102 and with a rib portion 109 made of a resin interposed therebetween, and a sealing resin portion 106 is provided around the chip 103 and the glass 105 on the substrate 2.

In such a package structure, the rib portion 109 is a portion at which the glass is adhered to the chip 103, and is a portion that suppresses a sealing resin material for forming the sealing resin portion 106 from wetting and spreading toward the inner side of the chip 103. The rib portion 109 is formed along the surroundings of the glass 105 to from a hollow portion 108 between the chip 103 and the glass 105.

The package structure illustrated in FIG. 5 is provided with a plurality of wires 104 that electrically connect the chip 103 to the substrate 102. Furthermore, a plurality of solder balls 117 are disposed as external connection terminals on a back side of the substrate 102.

The package structure illustrated in FIG. 5 employs a configuration that is provided with the rib portion 109 that supports the glass 105 on the chip 103, and therefore needs an area for disposing the rib portion 109 on a front side of the chip 103. This may be a factor that prevents miniaturization of the chip 103. Furthermore, a material and a process for forming the rib portion 109 are necessary, and therefore increase manufacturing cost accordingly.

Furthermore, two types of resin materials of the rib portion 109 and the sealing resin portion 106 are used, and therefore there is an interface 110 between respectively different resin materials in a configuration where the surroundings of the rib portion 109 are covered with the sealing resin portion 106. Detachment between resins may occur at the interface 110.

Detachment having occurred at the interface 110 between the rib portion 109 and the sealing resin portion 106 may become causes of cracking of the chip 103 starting from a detachment portion, disconnection of the wires 104, and the like. Furthermore, the detachment portion at the interface 110 between the rib portion 109 and the sealing resin portion 106 may form an air layer. The air layer is a portion that reflects light, and therefore reflected light from the air layer may become a cause that produces a flare when the reflected light enters the chip 103.

Hence, the solid-state imaging device 1 according to the present embodiment can achieve the semiconductor hollow package that one type of the resin material for forming the sealing resin portion 6 seals the image sensor 3 and the wires 4, and the sealing resin portion 6 also serves as the connection portion of the glass 5.

The solid-state imaging device 1 can eliminate the rib portion 109 illustrated in FIG. 5, so that an area for disposing the rib portion 109 on the front side of the image sensor 3 becomes unnecessary, and it is possible to miniaturize the image sensor 3. Miniaturization of the image sensor 3 can miniaturize the package structure of the solid-state imaging device 1. Furthermore, a material and a process for forming the rib portion 109 are unnecessary, so that it is possible to reduce manufacturing cost accordingly.

Furthermore, it is possible to eliminate the rib portion 109, so that it is possible to eliminate the interface between the respectively different resin materials, and prevent detachment at the interface between the resins. Consequently, it is possible to prevent cracking of an image sensor starting from the detachment portion of the interface between the resins, disconnection of bonding wires, and the like. Furthermore, it is possible to prevent occurrence of a flare caused by the air layer produced at the detachment portion of the interface between the resins.

Elimination of the rib portion 109 causes a problem that the sealing resin material 26 for forming the sealing resin portion 6 wets and spreads inside the image sensor 3. In this regard, according to the solid-state imaging device 1, the groove portion 21 that is the resin restriction portion 20 formed at the front surface portion of the image sensor 3 can suppress the sealing resin material 26 from wetting and spreading inside the image sensor 3.

Furthermore, in the solid-state imaging device 1, most of the portions on the upper sides of the side surfaces 5c of the glass 5 are the exposed surface portions 5d that are not covered with the sealing resin portion 6. According to this configuration, it is possible to reduce a tensile stress that acts on the glass 5 from the sealing resin portion 6 when the sealing resin portion 6 stretches and contracts as, for example, the temperature changes. Consequently, it is possible to reduce a risk that the side surfaces 5c of the glass 5 are cracked.

### 3. Modification Example of Solid-State Imaging Device According to First Embodiment

A modification example of the solid-state imaging device 1 according to the first embodiment of the present technology will be described.

### (First Modification Example)

Referring to FIG. 6, a first modification example of the solid-state imaging device 1 according to the first embodiment will be described. As illustrated in FIG. 6, in the first modification example, the image sensor 3 includes a plurality of groove portions 21 formed on the front surface 3a side of the image sensor 3. In the example illustrated in FIG. 6, the four groove portions 21 are formed in the peripheral circuit region 15.

Each groove portion 21 is formed in the endless shape so as to surround the entire circumference of the surroundings of the effective pixel region 14, and the four groove portions 21 are formed in parallel. That is, the plurality of (four) groove portions 21 multiply surround the effective pixel region 14. Accordingly, the entire lengths of the groove portions 21 become longer in order from the groove portion 21 on the inner circumferential side (the left side in FIG. 6) to the groove portion 21 on the outer circumferential side (the right side in FIG. 6). An interval between the neighboring groove portions 21 is, for example, substantially the same as the dimension of the groove width of the groove portion 21.

In the configuration according to the first modification example, ridge portions 22 having the heights corresponding to the groove depths of the groove portions 21 are formed between the neighboring groove portions 21. That is, the plurality of groove portions 21 are formed to form recess/protrusion portions 23 formed by alternately disposing the groove portions 21 and the ridge portions 22 at the periphery portion of the front surface 3a of the image sensor 3.

As described above, by forming the plurality of groove portions 21, it is possible to restrict intrusion of the sealing resin material by the groove portions 21 on the inner circumferential side even when, for example, the sealing resin material flows out to the inner side beyond the groove portions 21 on the outer circumferential side. Consequently, it is possible to effectively suppress intrusion of the sealing resin material toward the effective pixel region 14, and reliably prevent the sealing resin material from contaminating the effective pixel region 14.

Furthermore, even when the sealing resin material goes beyond the groove portions 21 on the outer circumferential side and flows out to the inner side, as the number of the groove portions 21 is larger, it is possible to suppress the sealing resin material from reaching the groove portion 21 on the innermost side until the applied sealing resin material is cured. Consequently, it is possible to increase the amount of the sealing resin material by forming the plurality of groove portions 21 compared to the configuration where only the one groove portion 21 is provided.

Note that, although the four groove portions 21 are formed in the example illustrated in FIG. 6, the number of the groove portions 21 is not limited. For example, the approximately 10 groove portions 21 may be formed in parallel. Furthermore, the plurality of groove portions 21 may be formed to have the common groove width and groove depth, or may be formed to have different groove widths and groove depths depending on formation portions or the like of the groove portions 21.

### (Second Modification Example)

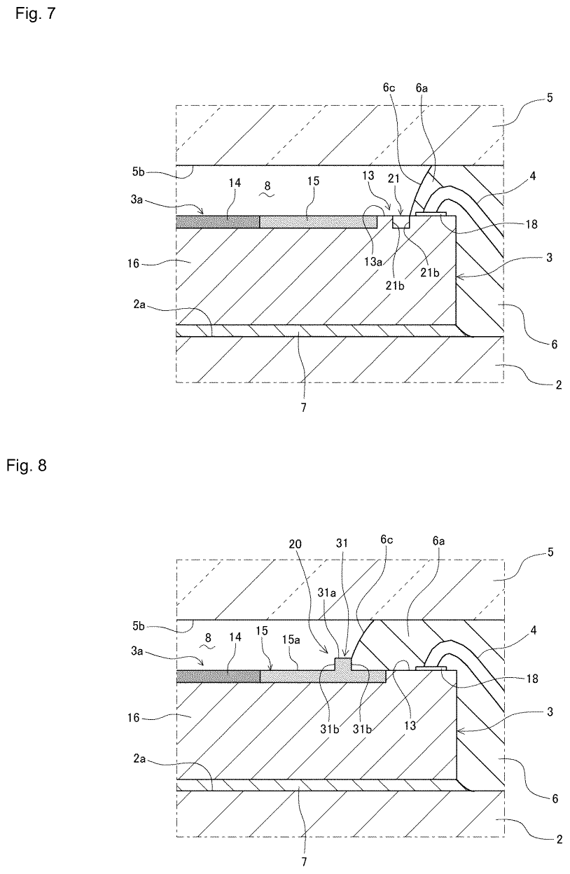

Referring to FIG. 7, a second modification example of the solid-state imaging device 1 according to the first embodiment will be described. As illustrated in FIG. 7, in the second modification example, the groove portion 21 is formed in the peripheral region 13 on the front surface portion of the image sensor 3. The groove portion 21 is formed on the inner side of the pad electrodes 18 that accept connection of the wires 4 in the peripheral region 13.

The groove portion 21 is formed at an exposed portion of the semiconductor substrate 16 that is a silicon portion in the peripheral region 13. The groove portion 21 is formed such that, for example, the angle formed between the left and right side surface portions 21b and the front surface 13a of the peripheral region 13 is substantially 90°. The groove portion 21 is formed in the peripheral region 13 by performing a cutting process on the portion of the semiconductor substrate 16 using a predetermined tool such as a dicing blade, or by a method that uses etching or the like.

Thus, the groove portion 21 may be formed in the peripheral region 13 at the front surface portion of the image sensor 3. By forming the groove portion 21 in the peripheral region 13, it is possible to stop at the outer circumferential side of the front surface portion of the image sensor 3 the sealing resin material for forming the sealing resin portion 6 from wetting and spreading to the inside.

Consequently, it is possible to effectively suppress intrusion of the sealing resin material toward the effective pixel region 14.

Note that, in the second modification example, the plurality of groove portions 21 may be formed in the peripheral region 13 similarly to the first modification example. Furthermore, the groove portions 21 may be formed in both of the peripheral circuit region 15 and the peripheral region 13.

### (Third Modification Example)

Referring to FIG. 8, a third modification example of the solid-state imaging device 1 according to the first embodiment will be described. As illustrated in FIG. 8, in the third modification example, the resin restriction portion 20 is provided as a ridge portion 31 formed on the front surface 3a side of the image sensor 3. In an example illustrated in FIG. 8, the one ridge portion 31 is provided.

The ridge portion 31 is formed in the peripheral circuit region 15 at the front surface portion of the image sensor 3. The ridge portion 31 is a protrusion portion of a frame shape with respect to the front surface 15a of the peripheral circuit region 15, and is formed in an endless shape so as to surround the entire circumference of the surroundings of the effective pixel region 14. The ridge portion 31 is formed into a rectangular frame shape along the outer shape of the image sensor 3 in plan view.

As illustrated in FIG. 8, the ridge portion 31 includes an upper surface portion 31a of a horizontal shape and left and right side surface portions 31b that oppose to each other, and these surface portions form a protrusion shape along the rectangular shape in a horizontal cross section. The ridge portion 31 is formed such that each of the width and the protrusion height is, for example, approximately several micrometers. The width of the ridge portion 31 is the dimension between the left and right side surface portions 31b, and the protrusion height of the ridge portion 31 is the dimension from the front surface 15a of the peripheral circuit region 15 to the upper surface portion 31a, that is, the dimension in the vertical direction of the side surface portion 31b. The ridge portion 31 can be formed by, for example, partially laminating an organic film for forming the peripheral circuit region 15 by patterning that uses, for example, the photolithography technique.

Thus, the resin restriction portion 20 may be provided as the ridge portion 31. According to such a configuration, the ridge portion 31 becomes a barrier portion, and the ridge portion 31 restricts intrusion of the sealing resin material into the inner side beyond the ridge portion 31 at the front surface portion of the image sensor 3 due to an action or the like of the surface tension. Note that an application amount of the sealing resin material is controlled as appropriate to restrict the intrusion of the sealing resin material to the inside.

By curing the sealing resin material in a state where the sealing resin material is held back by the ridge portion 31, the sealing resin portion 6 brings the lower portion of the inner side of the on-chip interposed portion 6a into contact with the side surface portion 31b (the right side surface portion 31b in FIG. 8) on the outer side of the ridge portion 31.

Note that, in the third modification example, a plurality of the ridge portions 31 may be provided in parallel. Furthermore, the ridge portions 31 may be formed in the peripheral region 13. Furthermore, the ridge portions 31 may be provided in parallel together with the groove portions 21.

### (Fourth Modification Example)

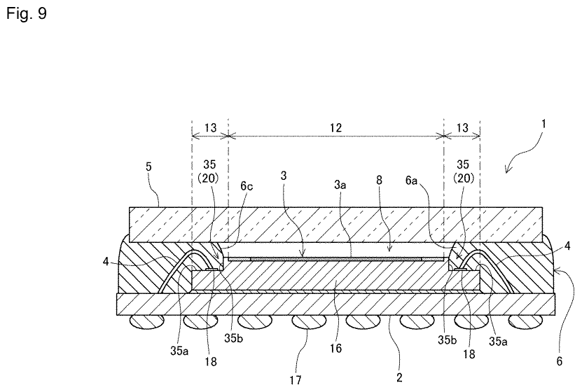

Referring to FIG. 9, a fourth modification example of the solid-state imaging device 1 according to the first embodiment will be described. As illustrated in FIG. 9, the image sensor 3 includes, on the front surface 3a side, a step portion 35 formed in the peripheral region 13 as the resin restriction portion 20.

The step portion 35 is formed on the front surface 3a side of the image sensor 3 and at the periphery portion of the image sensor 3. The step portion 35 is a portion that forms a step on a side lower than the other portion of the front surface 3a of the image sensor 3, that is, an inner portion surrounded by the step portion 35, and makes the thickness of the periphery portion of the image sensor 3 thinner than the thickness of the other portion. The step portion 35 forms a step surface 35a of a horizontal shape at a position lower than the front surface 3a formed by the front surface 15a of the peripheral circuit region 15 and the like.

The step portion 35 is formed in a region of a rectangular frame shape along the outer shape of the image sensor 3 in plan view such that the step portion 35 has a predetermined width for the step surface 35a. A side surface 35b that is a relative protrusion portion with respect to the step surface 35a at the front surface portion of the image sensor 3 is formed on the inner circumferential side of the step portion 35. The side surface 35b is, for example, a surface along the vertical direction.

According to the configuration where the image sensor 3 includes the step portion 35, the step surface 35a is an installation surface portion of the pad electrodes 18 that accept connection of the wires 4. The step surface 35a and the side surface 35b of the step portion 35 are surfaces covered with the sealing resin portion 6 together with the wires 4.

The step portion 35 is formed in the peripheral region 13 by performing the cutting process on the portion of the semiconductor substrate 16 using a predetermined tool, or by a method that uses etching or the like. Note that the step portion 35 is formed by making a layer structure for forming the pixel region 12 at the front surface portion of the image sensor 3 relatively higher than the front surface of the peripheral region 13.

Thus, the resin restriction portion 20 may be provided as the step portion 35. According to such a configuration, the side surface 35b of the step portion 35 becomes a barrier portion, and the step portion 35 restricts intrusion of the sealing resin material into the inside beyond the step portion 35 at the front surface portion of the image sensor 3 due to an action or the like of the surface tension. Note that an application amount of the sealing resin material is controlled as appropriate to restrict the intrusion of the sealing resin material to the inside.

By curing the sealing resin material in a state where the sealing resin material is held back by the step portion 35, the sealing resin portion 6 brings the lower portion of the inner side of the on-chip interposed portion 6a into contact with the side surface 35b of the step portion 35. The entire wires 4 including the connection portions of the wires 4 with respect to the pad electrodes 18 at the step portion 35 are sealed by the sealing resin portion 6.

### 4. Configuration Example of Solid-State Imaging Device According to Second Embodiment

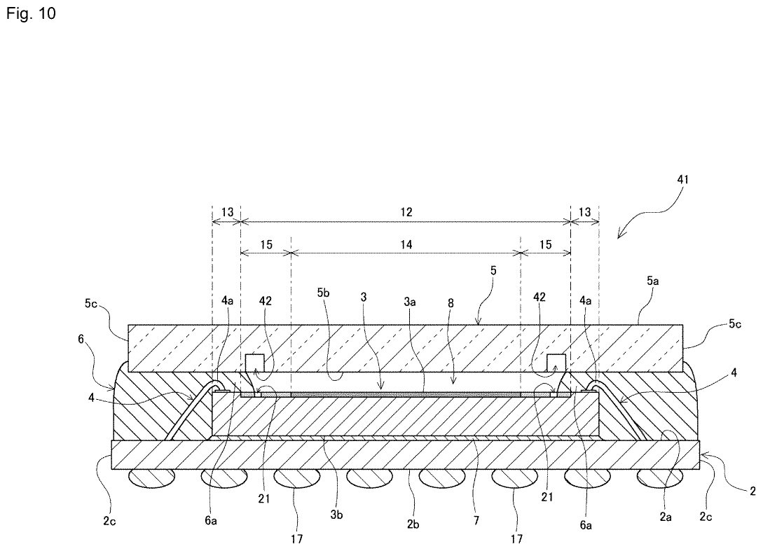

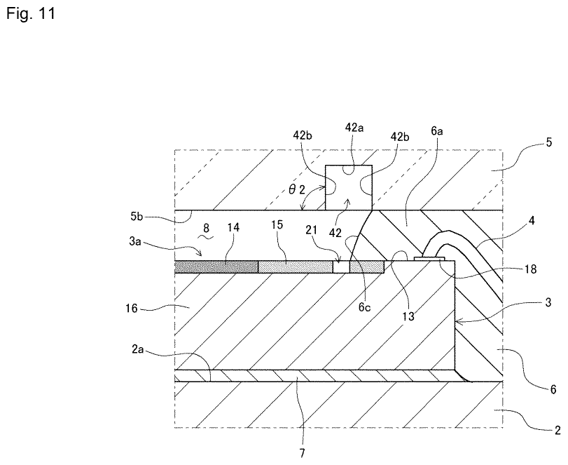

Referring to FIGS. 10 and 11, a configuration example of a solid-state imaging device 41 according to a second embodiment of the present technology will be described. In the following embodiments described below, configurations shared with or corresponding to those of the first embodiment are denoted by the same names or the same reference numerals, and descriptions about repeated contents will be omitted as appropriate.

As illustrated in FIGS. 10 and 11, in the solid-state imaging device 41 according to the present embodiment, the glass 5 includes, on the back surface 5b that is the surface on a side facing the image sensor 3, a glass groove portion 42 that is a groove portion for restricting intrusion of the sealing resin material for forming the sealing resin portion 6 into the inside of the glass 5.

The glass groove portion 42 is formed on a back surface 5b side of the glass 5 and at a portion meeting the peripheral circuit region 15 of the image sensor 3 in plan view. The glass groove portion 42 is an excavated portion in the back surface 5b of the glass 5, and is formed in an endless shape so as to surround the entire circumference of the surroundings of effective pixel region 14 of the image sensor 3 in plan view. The glass groove portion 42 is formed into, for example, a rectangular frame shape along the outer shape of the glass 5 in plan view.

As illustrated in FIG. 11, the glass groove portion 42 includes a bottom surface portion 42a of a horizontal shape that is the surface on the upper side, and left and right side surface portions 42b that face each other, and these surface portions form a groove shape of a substantially “U” shape in a horizontal cross section. That is, the glass groove portion 42 is formed as a rectangular groove whose lower side is an open side and that has a horizontal cross-sectional shape along the rectangular shape.

The glass groove portion 42 is formed such that the left and right side surface portions 42b are vertical surfaces. Hence, an angle θ2 formed between the left and right side surface portions 42b and the back surface 5b of the glass 5 is approximately 90° in horizontal cross-sectional view. In this regard, a value of the angle θ2 in horizontal cross-sectional view of a corner portion formed between the side surface portion 42b and the back surface 5b is not limited in particular. The angle θ2 is set to a value within a range of, for example, 60 to 90°. Furthermore, the angle θ2 may be an obtuse angle.

The glass groove portion 42 is formed such that each of the groove width and the groove depth is, for example, approximately several micrometers. This is just an example, and the glass groove portion 42 is formed such that the groove width is approximately 10 μm and the groove depth is approximately 10 μm. The groove width of the glass groove portion 42 is the dimension between the left and right side surface portions 42b, and the groove depth of the glass groove portion 42 is the dimension from the bottom surface portion 42a to the back surface 5b of the glass 5, that is, the dimension in the vertical direction of the side surface portion 42b.

The glass groove portion 42 is formed by performing the cutting process using a predetermined tool such as a dicing blade, or by a method that uses etching as processing for the glass 5 or the like.

The glass groove portion 42 functions as a resin restriction portion that holds back the flow of the sealing resin material on the back surface 5b side of the glass 5 mounted on the applied sealing resin material in the process of forming the sealing resin portion 6. That is, the glass groove portion 42 restricts intrusion of the sealing resin material applied to the outer circumferential side of the image sensor 3 to the inner side (the effective pixel region 14 side in plan view) beyond the glass groove portion 42 on the back surface 5b of the glass 53

By curing the sealing resin material in a state where the inflow of the sealing resin material to the glass groove portion 42 is held back, the inner side of the on-chip interposed portion 6a of the sealing resin portion 6 is located at an edge end of the corner portion formed between the side surface portion 42b (the right side surface portion 42b in FIG. 10) on the outer side of the glass groove portion 42 and the back surface 5b of the glass 5. That is, the sealing resin portion 6 is formed such that the inner side surface 6c of the on-chip interposed portion 6a substantially continues to the side surface portion 42b on the outer side of the glass groove portion 42.

Note that the glass groove portion 42 may allow the sealing resin material to flow into the groove as long as the glass groove portion 42 does not allow the sealing resin material to intrude the inner side beyond the glass groove portion 42. In this case, the glass groove portion 42 internally includes part of the sealing resin portion 6 whose sealing resin material has been cured.

According to the solid-state imaging device 41 according to the present embodiment, the following effects can be obtained in addition to the effects obtained by the solid-state imaging device 1 according to the first embodiment. That is, the glass groove portion 42 is formed on the back surface 5b side of the glass 5, and consequently can effectively suppress the sealing resin material from wetting and spreading inside the image sensor 3 together with the groove portion 21 formed at the front surface portion of the image sensor 3. Furthermore, the glass groove portion 42 can suppress the sealing resin material from flowing toward a region above the effective pixel region 14 on the back surface 5b of the glass 5. Consequently, it is possible to suppress part of incident light on the effective pixel region 14 from being blocked, that is, occurrence of so-called vignetting of the incident light.

As described above, the solid-state imaging device 41 according to the present embodiment includes the resin restriction portions on both of the image sensor 3 and the glass 5. Note that, although the one glass groove portion 42 is formed in the examples illustrated in FIGS. 10 and 11, the number of the glass groove portions 42 is not limited, and a plurality of the glass groove portions 42 may be formed in parallel. Furthermore, the plurality of glass groove portions 42 may be formed to have the common groove width and groove depth, or may be formed to have different groove widths and groove depths depending on formation portions or the like of the glass groove portions 42.

### 5. Modification Example of Solid-State Imaging Device According to Second Embodiment

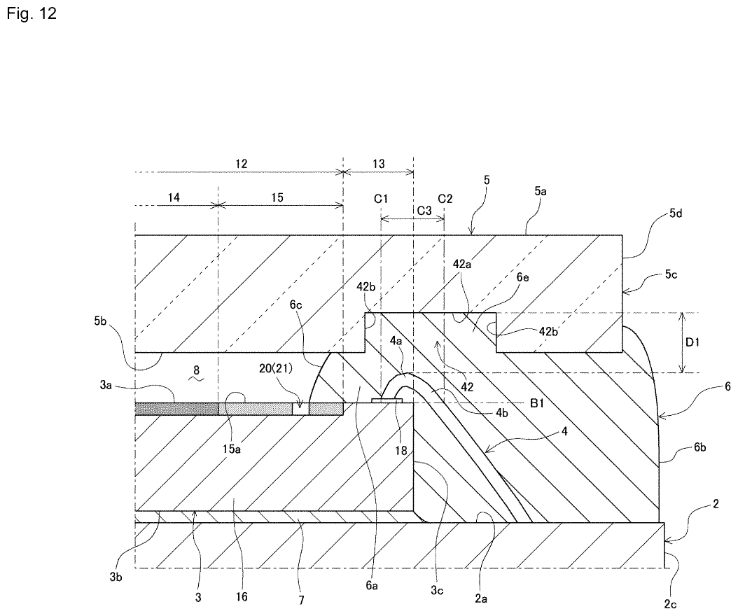

Referring to FIG. 12, a modification example of the solid-state imaging device 41 according to the second embodiment of the present technology will be described.

As illustrated in FIG. 12, in this modification example, the glass groove portion 42 that functions as the resin restriction portion is formed as a portion for preventing an interference between the wires 4 and the glass 5. The glass groove portion 42 includes a portion located on the outer side of the outer shape of the image sensor 3 in plan view. That is, the glass groove portion 42 includes a portion located on the outer side (the right side in FIG. 12) of the side surfaces 3c that form the outer shape of the image sensor 3 in plan view.

The glass groove portion 42 is formed in a region including at least part of a portion (hereinafter, referred to as a “wire upper portion”) 4b of the wire 4 existing at the position higher than the front surface 3a of the image sensor 3. The wire upper portion 4b is a portion that includes the top portion 4a, and a portion that forms a mountain shape protruding toward the upper side.

As illustrated in FIG. 12, the wire upper portion 4b is a portion of the wire 4 on the upper side of a virtual straight line B1 indicating a height position of the front surface 3a of the image sensor 3. In other words, the wire upper portion 4b is a portion of the wire 4 in a range of a range C3 from a position C1 at an inner end of the connection portion with respect to the pad electrode 18 to a position C2 at an outermost end on the virtual straight line B1 in a horizontal direction (lateral direction).

In the configuration according to the present modification example, the groove width of the glass groove portion 42 is formed in a region including the entire wire upper portion 4b in plan view. More specifically, the glass groove portion 42 includes the side surface portion 42b on the inner side (the left side in FIG. 12) located at a position above the peripheral region 13 and on the inner side of the position C1 of the inner end of the connection portion of the wire 4 with respect to the pad electrode 18. Furthermore, the glass groove portion 42 includes the side surface portion 42b on the outer side (the right side in FIG. 12) located at a position on the outer side of the outer shape of the image sensor 3 and on the outer side of the position C2 of the outermost end on the virtual straight line B1 of the wire 4.

According to the configuration where the glass 5 includes the glass groove portion 42 for avoiding the interference with the wires 4, the glass mounting process of the manufacturing method for the solid-state imaging device 41 adopts a following mode.

The glass 5 is mounted on the sealing resin material 26 (see FIG. 3C) in a state where the sealing resin material is applied so as to cover the entire wires 4 such that the entire formation portion of the glass groove portion 42 is mounted covering the sealing resin material 26 from above. The mounted glass 5 sinks in the sealing resin material 26 due to the weight of the glass 5, so that the sealing resin material 26 is filled in the glass groove portion 42.

Hence, in a state where the sealing resin material 26 is cured and the sealing resin portion 6 is formed, the entire or substantially entire interior of the glass groove portion 42 is buried with the sealing resin portion 6 in a cured state. That is, the sealing resin portion 6 includes an intra-groove resin portion 6e that exists in the glass groove portion 42.

According to the configuration according to this modification example, it is possible to reduce a risk that the wires 4 interfere with the glass 5. More specifically, as illustrated in FIG. 12, by forming the glass groove portion 42 in the glass 5, it is possible to increase a distance between an upper end (vertex) of the wire 4 formed by the top portion 4a of the wire 4, and the glass 5 by the length corresponding to the groove depth of the glass groove portion 42. That is, a distance between the upper end of the wire 4 and a lower surface side of the glass 5 can be a distance D1 between the upper end of the wire 4 and the bottom surface portion 42a of the glass groove portion 42.

Consequently, the glass groove portion 42 can allow the glass 5 to escape from the wire upper portion 4b of the wire 4, and avoid the interference between the wire 4 and the glass 5. Consequently, by reducing the application amount of the sealing resin material to suppress the sealing resin material from wetting and spreading on the front surface 3a of the image sensor 3, it is possible to make the wires 4 hardly interfere with the glass 5. In other words, it is possible to reduce the application amount of the sealing resin material, so that it is possible to suppress the sealing resin material from wetting and spreading on the image sensor 3.

Note that the glass groove portion 42 is formed such that the entire wire upper portion 4b is located in a range of the groove width in plan view in the example illustrated in FIG. 12, the present technology is not limited to such a configuration. The glass groove portion 42 may be formed such that part of the wire upper portion 4b including the top portion 4a in plan view such as a portion near the top portion 4a of the wire upper portion 4b is located in the range of the groove width.

### 6. Configuration Example of Solid-State Imaging Device According to Third Embodiment

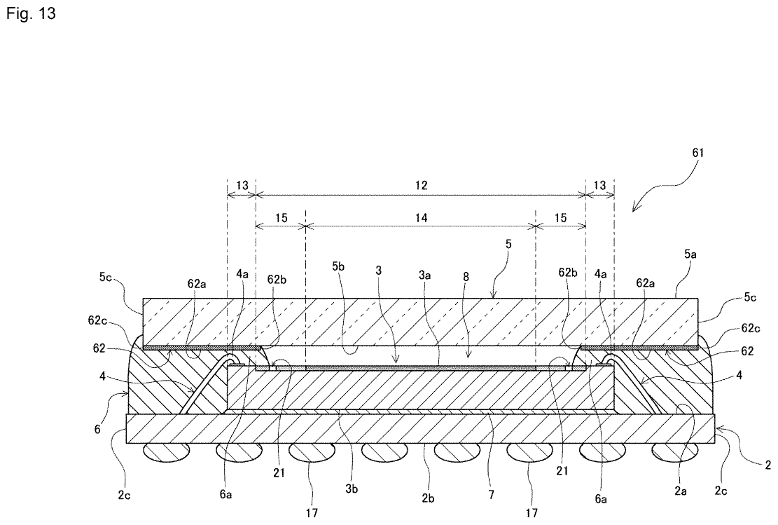

Referring to FIG. 13, a configuration example of a solid-state imaging device 61 according to a third embodiment of the present technology will be described.

As illustrated in FIG. 13, the solid-state imaging device 61 according to the present embodiment includes a resin film portion 62 provided on the back surface 5b of the glass 5. The resin film portion 62 is provided on the back surface 5b side of the glass 5 as a dam portion that restricts intrusion of the sealing resin material for forming the sealing resin portion 6 into the inside of the glass 5.

The resin film portion 62 is a portion having a predetermined thickness, and this film thickness forms a ridge portion that protrudes from the back surface 5b of the glass 5. That is, the resin film portion 62 includes a front surface 62a that is a lower surface thereof and is located on a lower side corresponding to the film thickness below the back surface 5b of the glass 5. The resin film portion 62 is just an example, and is formed to have the film thickness of approximately several micrometers to 10 μm.

The resin film portion 62 is provided on the back surface 5b side of the glass 5 and at a periphery portion along the outer shape of the glass 5. The resin film portion 62 is formed in a region of a rectangular frame shape including a side portion of a predetermined width along each side of the planar view outer shape of the rectangular shape of the glass 5. Hence, the resin film portion 62 forms the protrusion portion of the rectangular frame shape on the back surface 5b side of the glass 5, and includes at each side portion an inner side surface 62b that is the side surface on the inner circumferential side and an outer side surface 62c that is the side surface on the outer circumferential side.

The resin film portion 62 includes the inner side surface 62b that is an edge end on the inner circumferential side and is located above the peripheral circuit region 15 of the image sensor 3. Furthermore, the resin film portion 62 matches the outer side surface 62c that is an edge end on the outer circumferential side with the position of the side surface 5c of the glass 5. In this regard, a formation range of the resin film portion 62 is not particularly limited as long as the formation range is a region that is on the outer side of the effective pixel region 14 of the image sensor 3 in plan view.

The resin film portion 62 is formed by, for example, a known film formation method such as printing or deposition on the back surface 5b of the glass 5. The resin film portion 62 is formed in advance by a process of forming the resin film portion 62 on the glass 5 at a time of the glass mounting process (see FIG. 3C) of mounting the glass 5 on the sealing resin material 26. That is, the glass 5 including the resin film portion 62 is mounted on the sealing resin material 26 in an applied state.

The front surface 62a of the resin film portion 62 is entirely covered with the sealing resin portion 6. In the glass mounting process, the glass 5 is mounted on the sealing resin material 26 by bringing the front surface 62a of the resin film portion 62 entirely in contact with the sealing resin material 26.

As the resin material for forming the resin film portion 62, for example, thermosetting resins such as a phenol-based resin, a silicone-based resin, an acrylic-based resin, an epoxy-based resin, an urethane-based resin, a silicon resin, and a polyetherimide-based resin, thermoplastic resins such as polyamideimide, polypropylene, and liquid crystal polymer, a photosensitive resin such as a UV curing resin that is an acrylic-based resin, a rubber, and other known resin materials are used alone or by combining a plurality of resin materials.

Furthermore, the resin film portion 62 is formed as a light-blocking film that has a light-blocking function. The resin film portion 62 that is the light-blocking film is formed of a resin material that has the property that has low reflectance and absorbs light. More specifically, as the material of the resin film portion 62, a resin material containing a black pigment such as carbon black or titanium black is used. Consequently, it is possible to make the resin film portion 62 become a black portion, and function as the light-blocking film.

According to the solid-state imaging device 61 according to the present embodiment, the following effects can be obtained in addition to the effects obtained by the solid-state imaging device 1 according to the first embodiment. That is, the resin film portion 62 can form a step on the back surface 5b side of the glass 5. Consequently, it is possible to effectively suppress the sealing resin material from wetting and spreading inside the image sensor 3 together with the groove portion 21 formed at the front surface portion of the image sensor 3. Furthermore, the resin film portion 62 can suppress the sealing resin material from flowing toward a region above the effective pixel region 14 on the back surface 5b of the glass 5. Consequently, it is possible to suppress occurrence of vignetting of incident light.

As described above, the solid-state imaging device 61 according to the present embodiment includes the resin restriction portions on both of the image sensor 3 and the glass 5. Note that the resin film portion 62 may be provided together with the glass groove portion 42.

Furthermore, the resin film portion 62 is the light-blocking film, so that it is possible to suppress occurrence of a flare caused when light having transmitted through the glass 5 is reflected by the sealing resin portion 6, the wires 4 or the like and enters the light receiving unit of the image sensor 3.

### 7. Modification Example of Solid-State Imaging Device According to Third Embodiment

Modification examples of the solid-state imaging device 61 according to the third embodiment of the present technology will be described. The modification examples according to the third embodiment are modification examples of the formation range of the resin film portion 62.

### (First Modification Example)

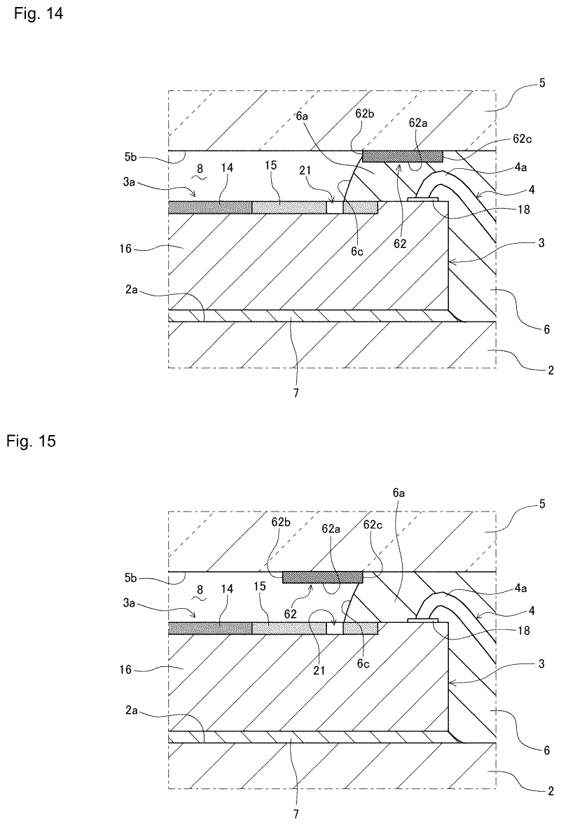

Referring to FIG. 14, a first modification example of the solid-state imaging device 61 according to the third embodiment will be described. As illustrated in FIG. 14, in the first modification example, the resin film portion 62 is provided as a portion having a narrow width compared to the example illustrated in FIG. 13.

In this modification example, the resin film portion 62 is formed on the back surface 5b side of the glass 5 and in a region corresponding to the periphery portion of the image sensor 3 in plan view. More specifically, the resin film portion 62 includes the inner side surface 62b located above the periphery portion of the peripheral circuit region 15 of the image sensor 3. Furthermore, the resin film portion 62 matches the outer side surface 62c with the position of the side surface 3c of the image sensor 3. In the example illustrated in FIG. 14, the outer side surface 62c of the resin film portion 62 is located slightly closer to the inner side than the side surface 3c of the image sensor 3 in lateral cross-sectional view, and is located near the top portion 4a of the wire 4.

The front surface 62a of the resin film portion 62 is entirely covered with the on-chip interposed portion 6a of the sealing resin portion 6. In the glass mounting process, the glass 5 is mounted on the sealing resin material 26 by bringing the front surface 62a of the resin film portion 62 entirely in contact with the sealing resin material 26.

According to the configuration of the first modification example, it is possible to reduce the amount of the resin material for forming the resin film portion 62 compared to the configuration illustrated in FIG. 13, and consequently reduce cost accordingly. Furthermore, by locating the outer side surface 62c of the resin film portion 62 closer to the inner side than the side surface 5c of the glass 5, it is possible to form the step portion of the outer side surface 62c and the back surface 5b of the glass 5, so that it is possible to improve the function of the resin restriction portion of the resin film portion 62 for the sealing resin material. Furthermore, the resin film portion 62 is the light-blocking film in the configuration according to the first modification example, too, so that it is possible to suppress occurrence of a flare.

### (Second Modification Example)

Referring to FIG. 15, a second modification example of the solid-state imaging device 61 according to the third embodiment will be described. As illustrated in FIG. 15, in the second modification example, the resin film portion 62 is provided at a position closer to the inner side compared to the first modification example illustrated in FIG. 14.

In this modification example, the resin film portion 62 is provided on the back surface 5b side of the glass 5 and in a region corresponding to the peripheral circuit region 15 in plan view. That is, the resin film portion 62 includes each of the inner side surface 62b and the outer side surface 62c located above the peripheral circuit region 15 of the image sensor 3. Hence, the outer side surface 62c of the resin film portion 62 is located closer to the inner side than the connection portion of the wire 4 with respect to the pad electrode 18 in lateral cross-sectional view.

The resin film portion 62 is located on the inner side of the on-chip interposed portion 6a, and is a provided in a state where the front surface 62a is entirely exposed and the outer side surface 62c is entirely covered with the sealing resin portion 6. In the glass mounting process, the glass 5 is mounted on the sealing resin material 26 (see FIG. 3C) in a state where the sealing resin material is applied so as to cover the entire wires 4 such that the entire or substantially entire resin film portion 62 is located closer to the inner side (inner circumferential side) than the sealing resin material 26.

According to the configuration according to the second modification example, the resin film portion 62 is located closer to the inner side than the formation region of the sealing resin portion 6 compared to the configuration according to the first modification example illustrated in FIG. 14, it is possible to make the step portion formed by the outer side surface 62c and the back surface 5b of the glass 5 effectively function as the dam portion, so that it is possible to improve the function of the resin restriction portion of the resin film portion 62 for the sealing resin material. Furthermore, the resin film portion 62 is the light-blocking film in the configuration according to the second modification example, so that it is possible to effectively suppress occurrence of a flare since the resin film portion 62 is close to the effective pixel region 14.

Note that, although the resin film portion 62 is provided as the ridge portion on the back surface 5b side of the glass 5 in the present embodiment, the configuration of the ridge portion is not limited to such a configuration. The configuration where the ridge portion is provided on the back surface 5b side of the glass 5 may be a configuration where, for example, a protrusion portion of a frame shape is formed as part of the glass 5 itself, that is, a shape portion of the glass 5 itself on the back surface 5b side by the cutting processing, etching, or the like.

### 8. Configuration Example of Solid-State Imaging Device According to Fourth Embodiment

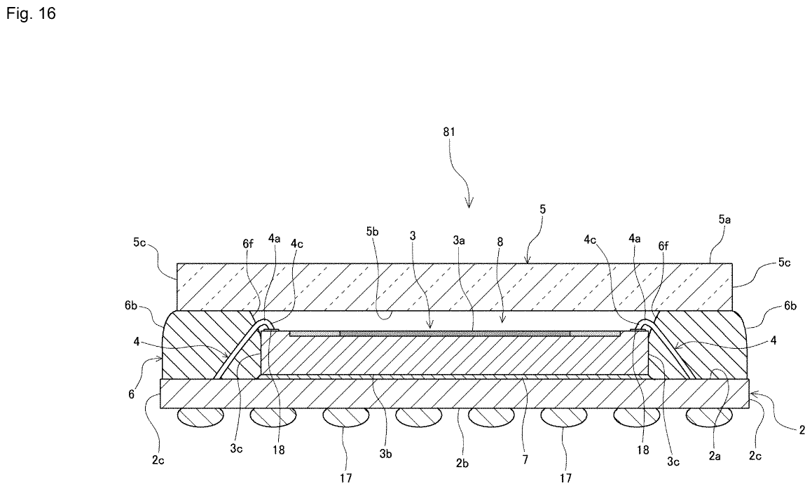

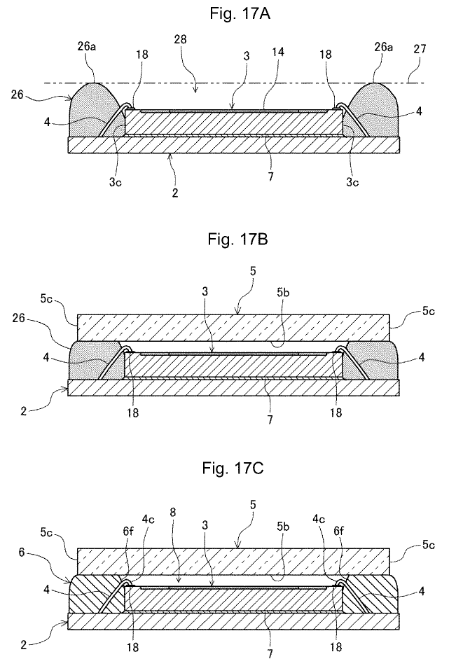

Referring to FIG. 16, a configuration example of a solid-state imaging device 81 according to a fourth embodiment of the present technology will be described. The solid-state imaging device 81 according to the present embodiment differs in that the image sensor 3 does not include the resin restriction portion 20 (groove portion 21) and the formation mode of the sealing resin portion 6 is different upon comparison with the solid-state imaging device 1 according to the first embodiment.

As illustrated in FIG. 16, in the solid-state imaging device 81, the sealing resin portion 6 is formed in a state where part of the wires 4 including the connection portions of the wires 4 with respect to the pad electrodes 18 are exposed without covering the front surface 3a of the image sensor 3. That is, the sealing resin portion 6 covers the side surfaces 3c of the image sensor 3 and the connection portions of the wires 4 with respect to the substrate 2, and exposes the entire front surface 3a side of the image sensor 3 that accepts connection of the one end sides of the wires 4.

The sealing resin portion 6 is interposed between the substrate 2 and the glass 5 around the image sensor 3, and does not include a portion interposed between the image sensor 3 and the glass 5, that is, the on-chip interposed portion 6a (see FIG. 1). That is, the sealing resin portion 6 is formed in a peripheral wall shape to surround the image sensor 3 from the side surface 3c sides between the periphery portions of the substrate 2 and the glass 5. The sealing resin portion 6 exposes the connection portions of the wires 4 with respect to the image sensor 3, and covers the substantially entire side surfaces 3c or the entire side surfaces 3c except the upper end portions of the side surfaces 3c of the image sensor 3.

Thus, the sealing resin portion 6 is basically formed without protruding closer to the inner side than the outer shape of the image sensor 3 in plan view. Hence, the pad electrodes 18 formed at the periphery portion of the front surface 3a of the image sensor 3 are not covered with the sealing resin portion 6 and exposed.

The sealing resin portion 6 includes, on the outer circumferential side, the outer side surface 6b that substantially continues to the four side surfaces 2c of the substrate 2. The sealing resin portion 6 includes the outer side surface 6b located on the lower side of the glass 5, does not include the glass covering portion 6d (see FIG. 2), and is formed such that the entire side surfaces 5c of the glass 5 are exposed. Furthermore, the sealing resin portion 6 includes, on the inner circumferential side, an inner side surface 6f that is a cavity formation surface for forming the cavity 8 together with the front surface 3a of the image sensor 3 and the back surface 5b of the glass 5.

The sealing resin portion 6 brings the portion on the lower side of the inner circumferential side into contact with the side surfaces 3c of the image sensor 3, and forms the inner side surface 6f on the upper side of the inner circumferential side. The inner side surface 6f is entirely or substantially entirely located closer to the upper side than the front surface 3a of the image sensor 3. As illustrated in FIG. 16, the inner side surface 6f is an inclined surface that is inclined gradually from the inside to the outside from the lower side to the upper side. In this regard, an orientation of the inclination and the degree of the inclination of the inner side surface 6f are not limited. The inner side surface 6f may be, for example, a vertical surface along the vertical direction. Furthermore, the inner side surface 6f may be a curved surface, or may be a planar surface.

The sealing resin portion 6 includes a portion that is on the connection portion side of the wires 4 with respect to the pad electrode 18 and protrudes from the inner side surface 6f. Hence, the wire 4 includes an exposed portion 4c that is not covered with the sealing resin portion 6. The exposed portion 4c is a portion that includes the entire portion of the wire 4 closer to the inner side than the side surfaces 3c of the image sensor 3, and includes the top portion 4a.

### 9. Manufacturing Method for Solid-State Imaging Device According to Fourth Embodiment

Referring to FIG. 17, an example of a manufacturing method for the solid-state imaging device 81 according to the fourth embodiment of the present technology will be described.

Similarly to the case of the first embodiment, according to the manufacturing method for the solid-state imaging device 81, after the die-bonding process (see FIG. 3A) and the wire bonding process (see FIG. 3B) are performed, a process of applying the sealing resin material 26 is performed. In the process of applying the sealing resin material 26, as illustrated in FIG. 17A, the sealing resin material 26 is applied to cover the side surfaces 3c of the image sensor 3 and the connection portions of the wires 4 with respect to the substrate 2 around the image sensor 3 on the substrate 2. Here, the sealing resin material 26 is applied without being applied onto the front surface 3a of the image sensor 3 while exposing the connection portion sides of the wires 4 with respect to the image sensor 3.

Similar to the case of the first embodiment, the sealing resin material 26 is applied to locate the height of the upper end portion 26a on the common virtual horizontal plane 27 in a region portion that forms a rectangular frame shape in plan view along the planar view outer shape of the image sensor 3. The applied sealing resin material 26 forms on the upper side of the image sensor 3 the opening portion 28 of the substantially rectangular shape in plan view that the entire effective pixel region 14 faces.

In the process of applying the sealing resin material 26, the sealing resin material 26 is applied to keep the entire exposed state of the front surface 3a such that the sealing resin material 26 is not applied on the front surface 3a of the image sensor 3. Consequently, the sealing resin material 26 is suppressed from intruding toward the effective pixel region 14, and the sealing resin material 26 is prevented from contaminating the effective pixel region 14.

Next, a process of mounting the glass 5 on the sealing resin material 26 as illustrated in FIG. 17B is performed. In the glass mounting process, the exposed states of the front surface 3a of the image sensor 3 and the portions on the connection portion sides of the wires 4 with respect to the image sensor 3 are maintained.

Next, the process of curing the sealing resin material 26 is performed, then the sealing resin material 26 is cured, and the sealing resin portion 6 is formed as illustrated in FIG. 17C. Furthermore, the process of forming the plurality of solder balls 17 on the back surface 2b side of the substrate 2 (see FIG. 4C) is performed. According to the above manufacturing process, the solid-state imaging device 81 employing the configuration that includes the exposed portions 4c of the wires 4, and in which the entire front surface 3a of the image sensor 3 is exposed from the sealing resin portion 6 as illustrated in FIG. 16 can be obtained.

According to the solid-state imaging device 81 and the manufacturing method therefor according to the present embodiment, it is possible to miniaturize the image sensor 3 and reduce manufacturing cost, and eliminate a failure caused by detachment at an interface between resins similar to the case of the first embodiment.

Furthermore, according to the solid-state imaging device 81 according to the present embodiment, the sealing resin portion 6 is not formed on the front surface 3a of the image sensor 3, so that it is possible to suppress the sealing resin material 26 from wetting and spreading inside the image sensor 3 without providing the resin restriction portion 20 (groove portion 21) in the image sensor 3. Note that it is possible to effectively suppress the sealing resin material 26 from wetting and spreading by providing the resin restriction portion 20 in the image sensor 3 in the present embodiment.

Furthermore, the configuration where the sealing resin portion 6 seals the side surfaces 3c of the image sensor 3, and fixes the image sensor 3 and the glass 5 can suppress a warp of the image sensor 3 due to expansion and contraction of the substrate 2 caused by a change in a use environmental temperature or the like.

Furthermore, in the solid-state imaging device 81, the pad electrodes 18 are not covered with the sealing resin portion 6, and the wire 4 includes the exposed portion 4c that is a portion that is not covered with the sealing resin portion 6. According to such a configuration, deformation such as deflection deformation of the exposed portion 4c of the wire 4 can absorb the expansion and the contraction of the sealing resin portion 6 caused by the change in the use environmental temperature or the like. Consequently, it is possible to suppress a stress produced by the expansion and the contraction of the sealing resin portion 6 from being applied to the connection portions of the wires 4 and the vicinity thereof with respect to the pad electrodes 18, so that it is possible to suppress disconnection at the connection portions of the wires 4 with respect to the pad electrodes 18 or disconnection of the wires 4 itself.

Furthermore, in the present embodiment, the sealing resin portion 6 may be formed such that the entire side surfaces 5c of the glass 5 are exposed. According to such a configuration, it is possible to effectively reduce a tensile stress that acts on the glass 5 from the sealing resin portion 6, and effectively reduce a risk that the side surfaces 5c of the glass 5 are cracked.

### 10. Configuration Example of Solid-State Imaging Device According to Fifth Embodiment

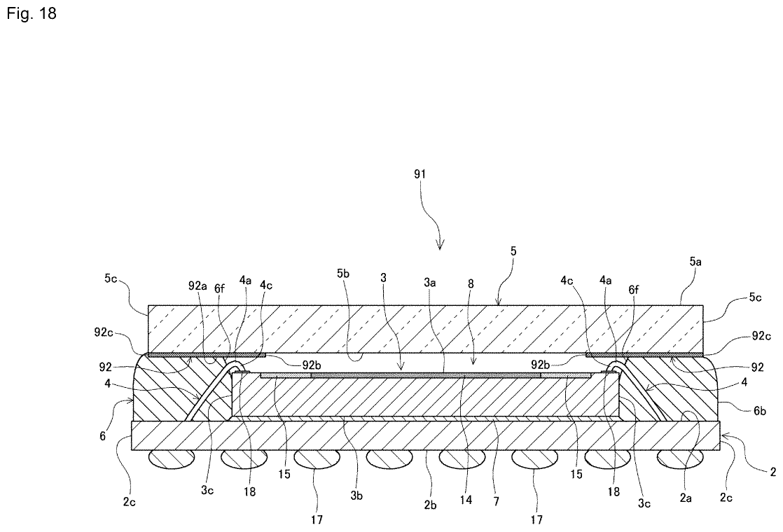

Referring to FIG. 18, a configuration example of a solid-state imaging device 91 according to a fifth embodiment of the present technology will be described.

As illustrated in FIG. 18, the solid-state imaging device 91 according to the present embodiment includes a light-blocking film portion 92 provided on the back surface 5b of the glass 5 in the solid-state imaging device 81 according to the fourth embodiment. The light-blocking film portion 92 is provided on the back surface 5b side of the glass 5 as a resin restriction portion that restricts intrusion of the sealing resin material for forming the sealing resin portion 6 into the inside of the glass 5.

The light-blocking film portion 92 is a portion having a predetermined thickness, and this film thickness forms a ridge portion that protrudes from the back surface 5b of the glass 5. That is, the light-blocking film portion 92 includes a front surface 92a that is a lower surface thereof and is located on a lower side corresponding to the film thickness below the back surface 5b of the glass 5. The light-blocking film portion 92 is just an example, and is formed to have the film thickness of approximately several micrometers to 10 μm.

The light-blocking film portion 92 is provided on the back surface 5b side of the glass 5 and at a periphery portion along the outer shape of the glass 5. The light-blocking film portion 92 is formed in a region of a rectangular frame shape including a side portion of a predetermined width along each side of the planar view outer shape of the rectangular shape of the glass 5. Hence, the light-blocking film portion 92 forms the protrusion portion of the rectangular frame shape on the back surface 5b side of the glass 5, and includes at each side portion an inner side surface 92b that is the side surface on the inner circumferential side and an outer side surface 92c that is the side surface on the outer circumferential side.

The light-blocking film portion 92 is provided covering the upper side of the connection portions of the wires 4 with respect to the image sensor 3. In the present embodiment, the light-blocking film portion 92 includes formation portions of the pad electrodes 18 that are the connection portions of the wires 4 on the front surface 3a of the image sensor 3, and is provided covering the entire exposed portions 4c of the wires 4 from above.

More specifically, the light-blocking film portion 92 includes the inner side surface 92b that is an edge end on the inner circumferential side and is located above the peripheral circuit region 15 of the image sensor 3. Furthermore, the light-blocking film portion 92 matches the outer side surface 92c that is an edge end on the outer circumferential side substantially with the position of the side surface 5c of the glass 5. In this regard, a formation range of the light-blocking film portion 92 is not particularly limited as long as the formation range is at least a region that covers part of the exposed portion 4c of the wire 4, particularly, the upper side of the connection portion of the wire 4 with respect to the image sensor 3, and a region that is on the outer side of the effective pixel region 14 of the image sensor 3 in plan view.

The light-blocking film portion 92 includes, on the inner circumferential side, an exposed portion 92d that is a portion that is not covered with the sealing resin portion 6. That is, the light-blocking film portion 92 includes a portion on an outer side surface 92c side as a portion that is covered with the sealing resin portion 6 from a front surface 92a side, and includes a portion on an inner side surface 92b side as the exposed portion 92d that is a portion that is not covered with the sealing resin portion 6. The entire exposed portions 4c of the wires 4 are covered with the exposed portion 92d of the light-blocking film portion 92 from above.

The light-blocking film portion 92 is formed of the same formation method and material as those of the resin film portion 62 that functions as the light-blocking film according to the third embodiment. The light-blocking film portion 92 is formed in advance by a process of forming the light-blocking film portion 92 on the glass 5 at a time of the glass mounting process (see FIG. 3C) of mounting the glass 5 on the sealing resin material 26. In the glass mounting process, the glass 5 is mounted on the sealing resin material 26 by bringing a portion on the outer circumferential side of the front surface 92a of the light-blocking film portion 92 in contact with the sealing resin material 26.

According to the solid-state imaging device 91 according to the present embodiment, the light-blocking film portion 92 can form a step on the back surface 5b side of the glass 5. Consequently, it is possible to suppress the sealing resin material from wetting and spreading to the inner side of the front surface 3a of the image sensor 3 and the inner side of the back surface 5b of the glass 5.

Furthermore, the light-blocking film portion 92 can suppress occurrence of a flare (gold wire flare) caused when light having transmitted through the glass 5 is reflected by the exposed portions 4c of the wires 4 or the like and enters the light receiving unit of the image sensor 3. Note that the light-blocking film portion 92 may be provided as a portion of a relatively narrow width by locating the outer side surface 92c above or near the side surfaces 3c of the image sensor 3 similarly to, for example, the resin film portion 62 illustrated in FIG. 14.

### 11. Configuration Example of Solid-State Imaging Device According to Sixth Embodiment

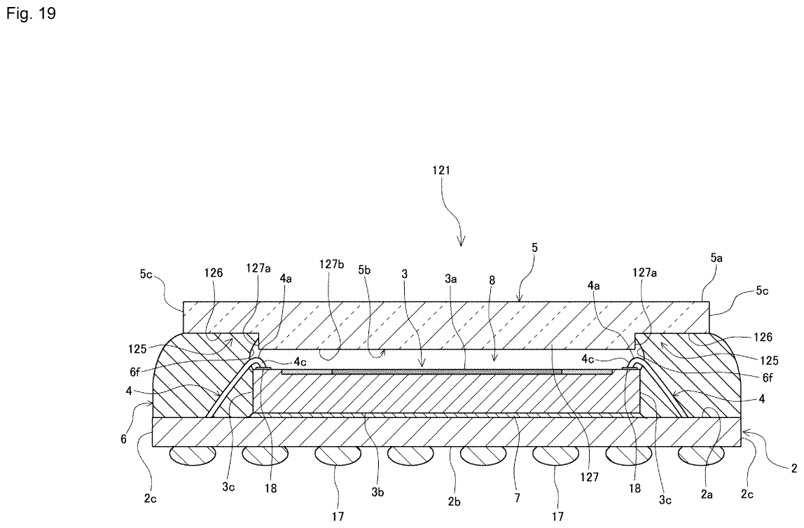

Referring to FIG. 19, a configuration example of a solid-state imaging device 121 according to a sixth embodiment of the present technology will be described.

As illustrated in FIG. 19, the solid-state imaging device 121 according to the present embodiment includes a step portion 125 on the back surface 5b side of the glass 5 facing the image sensor 3 in the solid-state imaging device 81 according to the fourth embodiment. The step portion 125 is formed on the back surface 5b side of the glass 5 and at the periphery portion of the glass 5, and forms a step surface 126 that is covered with the sealing resin portion 6.

The step portion 125 is a portion that forms a step on the upper side of the other portion of the back surface 5b of the glass 5, that is, an inner portion surrounded by the step portion 125, and makes the thickness of the periphery portion of the glass 5 thinner than the thickness of the other portion. The step portion 125 forms the step surface 126 of a horizontal shape at the periphery portion on the back side of the glass 5 and at a position higher than the back surface 5b of the other portion.

The step portion 125 is formed in a region of a rectangular frame shape along the outer shape of the glass 5 in plan view such that the step portion 125 has a predetermined width for the step surface 126. A relative protrusion surface portion 127 with respect to the step surface 126 at the back surface portion of the glass 5 is formed on the inner circumferential side of the step portion 125. The protrusion surface portion 127 includes side surfaces 127a formed at four sides, and a lower surface 127b of a horizontal shape. The side surface 127a is, for example, a surface along the vertical direction. Thus, the glass 5 includes the step surface 126 of the step portion 125 and the lower surface 127b of the protrusion surface portion 127 as the back surface 5b.

In the configuration where the glass 5 includes the step portion 125, the step surface 126 is a surface that accepts connection of the sealing resin portion 6 between the glass 5 and the substrate 2. The sealing resin portion 6 is formed such that the upper side of the inner side surface 6f is connected to the side surfaces 127a that form the step portion 125. The side surface 127a is a surface that is entirely or partially covered with the sealing resin portion 6 depending on the formation mode of the sealing resin portion 6.

As described above, the glass 5 according to the present embodiment includes, on the back surface 5b side, the protrusion surface portion 127 as a protrusion portion that forms the lower surface 127b that is a second surface portion located on an image sensor 3 side (lower side) with respect to the step surface 126 that is a first surface portion covered with the sealing resin portion 6. That is, the glass 5 is a protrusion-type glass that forms a protrusion shape in lateral cross-sectional view by the protrusion surface portion 127.

The protrusion surface portion 127 is formed to locate the side surfaces 127a above the exposed portion 4c of the wire 4. In an example illustrated in FIG. 19, the side surface 127a of the protrusion surface portion 127 is located above the top portion 4a of the wire 4. In this regard, the protrusion surface portion 127 may be formed such that, for example, the side surfaces 127a are located on the outer side of the side surfaces 3c of the image sensor 3.

The step portion 125 is formed by performing the cutting process using a predetermined tool such as a dicing blade, or by a method that uses etching as processing for the glass 5 or the like.

The step surface 126 of the glass 5 is entirely covered with the sealing resin portion 6. In the glass mounting process, the glass 5 is mounted on the sealing resin material 26 by bringing the step surface 126 entirely in contact with the sealing resin material 26.

According to the solid-state imaging device 121 according to the present embodiment, the following effects can be obtained in addition to the effects obtained by the solid-state imaging device 81 according to the fourth embodiment. That is, the step portion 125 of the glass 5 makes the side surfaces 127a of the protrusion surface portion 127 serve as barrier portions, so that it is possible to suppress the sealing resin material from wetting and spreading to the inside of the image sensor 3. Furthermore, the step portion 125 can suppress the sealing resin material from flowing toward a region above the effective pixel region 14 on the back surface 5b of the glass 5, and suppress occurrence of vignetting of incident light. As described above, the step portion 125 of the glass 5 is a portion that functions as the resin restriction portion.

Furthermore, according to a configuration where the glass 5 is a protrusion-type glass, it is possible to obtain a self-align effect of the surface tension of the sealing resin material 26 at a mounting position of the glass 5 in the glass mounting process for the sealing resin material 26. Consequently, it is possible to suppress positional shift of the mounting position of the glass 5.

### 12. Configuration Example of Solid-State Imaging Device According to Seventh Embodiment

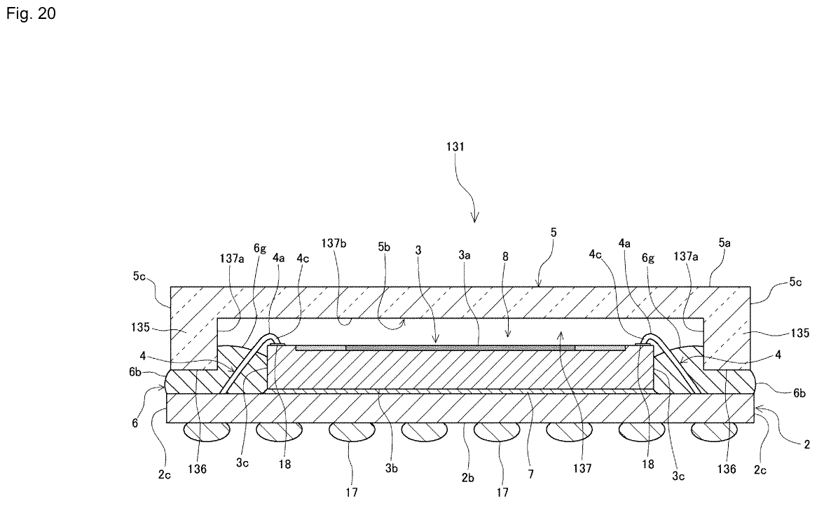

Referring to FIG. 20, a configuration example of a solid-state imaging device 131 according to a seventh embodiment of the present technology will be described.

As illustrated in FIG. 20, the solid-state imaging device 131 according to the present embodiment includes, at the periphery portion of the glass 5, a peripheral wall portion 135 that forms a contact portion with respect to the sealing resin portion 6. The peripheral wall portion 135 is provided in a region on the outer side of the image sensor 3 in plan view in the glass 5. In an example illustrated in FIG. 20, the peripheral wall portion 135 is formed so as to be located on the outer side of the connection potion of the wires 4 with respect to the substrate 2 in plan view.

The peripheral wall portion 135 is a portion that protrudes downward with respect to the other portion of the back surface 5b of the glass 5, that is, an inner portion surrounded by the peripheral wall portion 135, and makes the thickness of the periphery portion of the glass 5 thinner than the thickness of the other portion. The peripheral wall portion 135 forms the lower surface 136 of a horizontal shape at the periphery portion on the back side of the glass 5 and at a position lower than the back surface 5b of the other portion.

The peripheral wall portion 135 is formed in a region of a rectangular frame shape along the outer shape of the glass 5 in bottom view such that the peripheral wall portion 135 has a predetermined width for the lower surface 136. A relative recess portion 137 with respect to the lower surface 136 at the back surface portion of the glass 5 is formed on the inner circumferential side of the peripheral wall portion 135. That is, the glass 5 has the outer shape of a form obtained by digging one plate surface side of a plate glass in a rectangular shape, and has a form of a box shape whose lower side is an open side.

The recess portion 137 is formed by inner wall surfaces 137a of the four peripheral wall portions 135, and a bottom surface 137b of a horizontal shape. The inner wall surfaces 137a are, for example, surfaces along the vertical direction. As described above, the glass 5 includes the lower surface 136 of the peripheral wall portion 135 and the bottom surface 137b of the recess portion 137 as the back surface 5b.

In the glass 5, the peripheral wall portion 135 is a portion that accepts connection of the sealing resin portion 6 between the glass 5 and the substrate 2. The sealing resin portion 6 is interposed between the substrate 2 and the peripheral wall portion 135 around the image sensor 3. The sealing resin portion 6 accepts contact of the entire lower surface 136 of the peripheral wall portion 135, and covers lower portions of the inner wall surfaces 137a of the peripheral wall portion 135 and part (portions on the lower sides) of the side surfaces 3c of the image sensor 3. Note that the sealing resin portion 6 may be formed so as to entirely cover the inner wall surfaces 137a of the glass 5 and the side surfaces 3c of the image sensor 3, or may be formed so as to cover the periphery portion of the bottom surface 137b.

The sealing resin portion 6 make the outer side surface 6b that is the surface on the outer circumferential side substantially continue to the four side surfaces 2c of the substrate 2 and the side surfaces 5c of the glass 5. Furthermore, the sealing resin portion 6 includes an inner upper surface 6g that is a surface facing upward and faces the cavity 8 between the image sensor 3 and the peripheral wall portion 135.

The inner upper surface 6g is located between the side surfaces 3c of the image sensor 3 and the inner wall surfaces 137a of the peripheral wall portion 135. The sealing resin portion 6 includes a portion that is on the connection portion side of the wires 4 with respect to the pad electrodes 18 and protrudes as the exposed portion 4c from the inner upper surface 6g. In the example illustrated in FIG. 20, the sealing resin portion 6 is formed such that the upper end of the inner upper surface 6g is located at the substantially same height as the height of the front surface 3a of the image sensor 3. In this regard, the height of the upper end of the inner upper surface 6g is not limited.

As described above, the glass 5 according to the present embodiment includes, on the back surface 5b side, the recess portion 137 that forms the bottom surface 137b located on the upper side with respect to the lower surface 136 that is the contact surface with respect to the sealing resin portion 6. That is, the glass 5 is a recess-type glass that forms a recess shape in lateral cross-sectional view by the peripheral wall portions 135.

In the solid-state imaging device 131 including the recess-type glass as the glass 5, the cavity 8 is formed as the recess portion 137 of the glass 5. More specifically, the cavity 8 is a space in which the front surface 3a of the image sensor 3, the inner wall surfaces 137a and the bottom surface 137b of the glass 5, and the inner upper surface 6g of the sealing resin portion 6 face each other.

The peripheral wall portions 135 are formed by performing the cutting process using a predetermined tool such as a dicing blade, or by a method that uses etching or the like as processing for the glass 5.

### 13. Manufacturing Method for Solid-State Imaging Device According to Seventh Embodiment

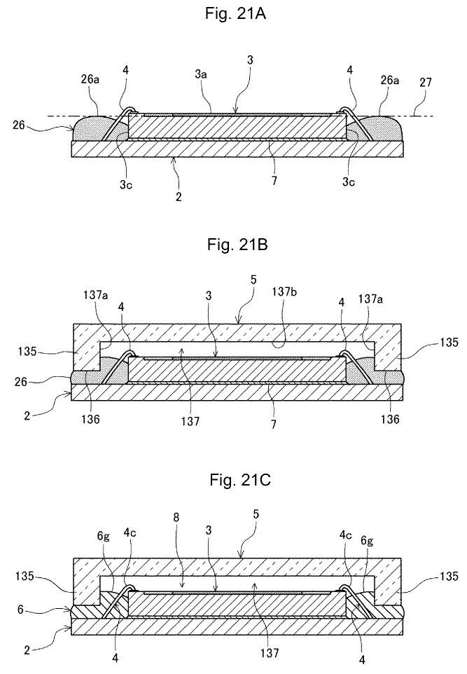

Referring to FIG. 21, an example of a manufacturing method for the solid-state imaging device 131 according to the seventh embodiment of the present technology will be described.

Similarly to the case of the first embodiment, according to the manufacturing method for the solid-state imaging device 131, after the die-bonding process (see FIG. 3A) and the wire bonding process (see FIG. 3B) are performed, the process of applying the sealing resin material 26 is performed. In the process of applying the sealing resin material 26, as illustrated in FIG. 21A, the sealing resin material 26 is applied to cover the side surfaces 3c of the image sensor 3 and the connection portions of the wires 4 with respect to the substrate 2 around the image sensor 3 on the substrate 2.

The sealing resin material 26 is applied to locate the height of the upper end portion 26a on the common virtual horizontal plane 27 in a region portion that forms a rectangular frame shape in plan view along the planar view outer shape of the image sensor 3 without being placed on the front surface 3a of the image sensor 3. Here, the sealing resin material 26 is applied such that the virtual horizontal plane 27 is at a position at the substantially same height as that of the front surface 3a of the image sensor 3 or lower than the front surface 3a. The sealing resin material 26 is applied without being placed on the front surface 3a of the image sensor 3, so that the sealing resin material 26 is suppressed from intruding toward the effective pixel region 14.

Next, a process of mounting the glass 5 on the sealing resin material 26 as illustrated in FIG. 21B is performed. The glass 5 is mounted on the sealing resin material 26 such that the peripheral wall portions 135 are mounted on the sealing resin material 26 while bringing the lower surface 136 entirely in contact with the sealing resin material 26. In a state where the glass 5 is mounted, the sealing resin material 26 is interposed between the peripheral wall portions 135 and the substrate 2.

Next, the process of curing the sealing resin material 26 is performed, then the sealing resin material 26 is cured, and the sealing resin portion 6 is formed as illustrated in FIG. 21C. Furthermore, the process of forming the plurality of solder balls 17 on the back surface 2b side of the substrate 2 (see FIG. 4C) is performed. According to the above manufacturing process, the solid-state imaging device 131 illustrated in FIG. 20 can be obtained.

According to the solid-state imaging device 131 according to the present embodiment, the following effects can be obtained in addition to the effects obtained by the solid-state imaging device 81 according to the fourth embodiment. That is, the glass 5 includes the peripheral wall portions 135 that form a protrusion structure on the back surface 5b side, so that it is possible to shorten a distance between the glass 5 and the substrate 2 at the peripheral portion of the image sensor 3 while securing the space of the cavity 8 on the image sensor 3.

Consequently, it is possible to reduce the amount of the sealing resin material for forming the sealing resin portion 6 compared to the configuration where, for example, the glass 5 is a member of a flat plate shape as a whole. Consequently, it is possible to suppress the sealing resin material from flowing onto the front surface 3a of the image sensor 3. Furthermore, the peripheral wall portions 135 can suppress the sealing resin material from flowing toward a region above the effective pixel region 14 on the back surface 5b of the glass 5, and suppress occurrence of vignetting of incident light. As described above, the peripheral wall portions 135 of the glass 5 are portions that function as the resin restriction portions.

### 14. Modification Example of Solid-State Imaging Device According to Seventh Embodiment

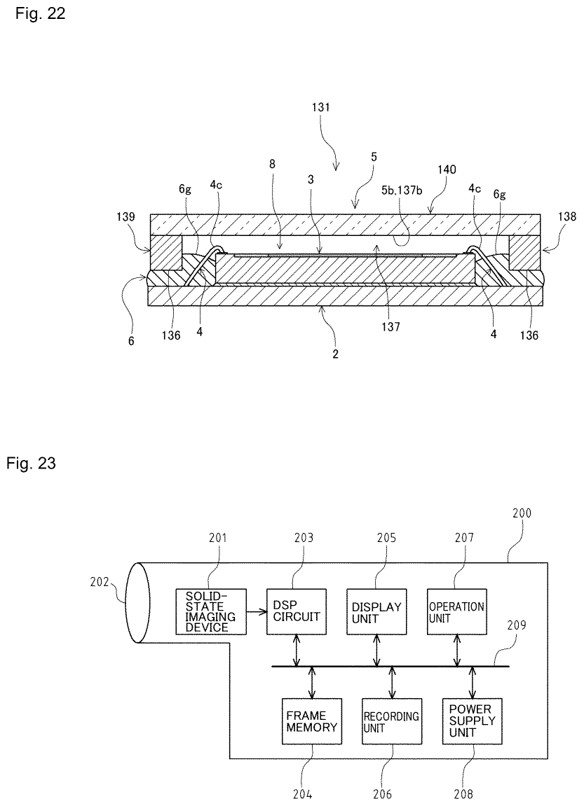

Referring to FIG. 22, a modification example of the solid-state imaging device 131 according to the seventh embodiment of the present technology will be described.

As illustrated in FIG. 22, in this modification example, a peripheral wall portion 138 provided on the back surface 5b side of the glass 5 is formed by a frame member 139 that is a separate member from the glass 5. That is, the glass 5 is formed in a recess-type shape as a glass with a frame.

The glass 5 includes a glass main body potion 140 that is formed of a glass plate of a rectangular plate shape, and the peripheral wall portion 138 that is formed of the frame member 139. The frame member 139 is a member that forms a rectangular frame shape in plan view, and is fixed by an adhesive or the like to the back surface 5b of the glass plate that forms the glass main body portion 140 of the glass 5.

The peripheral wall portion 138 forms the shape similar to that of the above-described peripheral wall portion 135 in the glass 5. That is, the peripheral wall portion 138 forms the lower surface 136 of the horizontal shape, and forms the recess portion 137 together with the glass main body portion in the glass 5.

As described above, the peripheral wall portion 138 may be a portion provided by attaching the frame member 139 of a separate member to the glass plate in the glass 5. The material of the frame member 139 is not limited in particular. Examples of the material of the frame member 139 include resin materials such as an epoxy resin, metal materials such as stainless steel and copper (Cu), inorganic materials such ceramics including glass or the like, and silicon.

### 15. Configuration Example of Electronic Device

Referring to FIG. 23, an application example of the semiconductor device to an electronic device according to the foregoing techniques will be described.

The semiconductor device (solid-state imaging device) according to the present technology can be applied as various devices that sense light such as visible light, infrared light, ultraviolet light, and an X ray. The solid-state imaging device according to the present technology can be applied to a general electronic device in which a solid-state imaging element is used in an image capturing unit (photoelectric conversion unit), such as a camera device such as a digital still camera or a video camera, a portable terminal device that has an imaging function, a copy machine in which a solid-state imaging element is used in an image reading unit, an in-vehicle sensor that shoots the front side, the rear side, surroundings, an interior of a car, and a distance measurement sensor that measures a distance between vehicles or the like. Furthermore, the solid-state imaging device may be formed as a one-chip or may be formed as a module in which an imaging unit and a signal processing unit or an optical system are collectively packaged with an imaging function.

As illustrated in FIG. 23, a camera device 200 as an electronic device includes an optical unit 202, a solid-state imaging device 201, a DSP (Digital Signal Processor) circuit 203, a frame memory 204, a display unit 205, a recording unit 206, an operation unit 207, and a power supply unit 208. The DSP circuit 203, the frame memory 204, the display unit 205, the recording unit 206, the operation unit 207, and the power supply unit 208 are properly connected to one another via a connection line 209, e.g., a bus line. For example, the solid-state imaging device 201 is any one of the solid-state imaging devices according to each of the foregoing techniques.

The optical unit 202 including a plurality of lenses captures incident light (image light) from a subject and forms an image on the imaging surface of the solid-state imaging device 201. The solid-state imaging device 201 converts the amount of incident light, for which an image is formed on the imaging surface by the optical unit 202, into an electric signal for each pixel and outputs the electric signal as a pixel signal.

The display unit 205 includes, for example, a panel-type display device such as a liquid crystal panel or an organic EL (Electro Luminescence) panel, and displays a moving image or a still image captured by the solid-state imaging device 201. The recording unit 206 records the moving image or the still image captured by the solid-state imaging device 201 in a recording medium such as a hard disk or a semiconductor memory.

The operation unit 207 issues operation commands for various functions of the camera device 200 in response to user operations. The power supply unit 208 properly supplies various power supplies serving as operation power supplies for the DSP circuit 203, the frame memory 204, the display unit 205, the recording unit 206, and the operation unit 207 to these targets of supply.

According to the above camera device 200, it is possible to miniaturize the image sensor 3 and reduce manufacturing cost, and eliminate a failure caused by detachment at an interface between resins for the solid-state imaging device 201.

The descriptions of the foregoing embodiments are merely examples of the present technology, and the present technology is not limited to the foregoing embodiments. For this reason, it is needless to say that various changes aside from the foregoing embodiments can be made according to the design and the like within the scope of the technical idea of the present disclosure. In addition, the advantages described in the present disclosure are merely exemplary and are not limited, and other advantages may be obtained. Furthermore, the configurations of the foregoing embodiments and the configurations of the modification examples can be combined as appropriate.

Although the semiconductor element is the image sensor 3 that is a light receiving element in the foregoing embodiments, the semiconductor element according to the present technology is not limited thereto. The semiconductor element according to the present technology may be, for example, light emission elements such as a Vertical Cavity Surface Emitting LASER (VCSEL), a laser diode, a Light Emitting Diode (LED). Furthermore, the imaging device that is the semiconductor device may employ a configuration including a plurality of semiconductor elements on one chip or a configuration including a plurality of semiconductor elements as a plurality of chips.

Furthermore, as for the foregoing embodiments, the solid-state imaging device preferably includes in at least one of the image sensor 3 and the glass 5 the configuration that restricts intrusion of the sealing resin material into the inside of the front surface 3a of the image sensor 3.

The present technology can have the following configurations.

(1)

A semiconductor device includes:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, and the semiconductor element includes, on a front side, a resin restriction portion that restricts intrusion of a resin material for forming the sealing resin portion into an inside of the semiconductor element.
   (2)

In the semiconductor device described in above (1), the resin restriction portion is one or a plurality of groove portions that are formed on the front side of the semiconductor element.

(3)

In the semiconductor device described in above (1) or above (2), the transparent member is a plate-like member whose one plate surface faces the semiconductor element, and has most of a portion on an upper side of a side surface as an exposed surface portion that is not covered with the sealing resin portion.

(4)

In the semiconductor device described in any one of above (1) to (3), the transparent member includes at least one of one or a plurality of groove portions and ridge portions on a surface on a side facing the semiconductor element, the groove portions and the ridge portions restricting the intrusion of the resin material for forming the sealing resin portion into the inside of the transparent member.

(5)

In the semiconductor device described in any one of above (1) to (4), the transparent member includes a groove portion on a surface on a side facing the semiconductor element,
the connection member is a wire whose upper side is disposed as a protrusion side such that an upper end is located at a position higher than a front surface of the semiconductor element, and
the groove portion is formed in a region including at least part of a portion of the connection member existing at the position higher than the front surface of the semiconductor element in plan view.
   (6)

The semiconductor device described in any one of above (1) to (5) further includes a resin film portion that is provided on a surface of the transparent member on a side facing the semiconductor element, and restricts the intrusion of the resin material for forming the sealing resin portion into the inside of the transparent member.

(7)

In the semiconductor device described in above (6), the resin film portion is formed as a light-blocking film.

(8)

In the semiconductor device described in any one of above (1) to (7), the semiconductor element includes a step portion as the resin restriction portion on the front side, the step portion forming a step formed at a periphery portion of the semiconductor element and on a side lower than an other portion of the semiconductor element, and forming a step surface that accepts connection of the connection member and is covered with the sealing resin portion.

(9)

A semiconductor device includes:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, and the sealing resin portion covers a side surface of the semiconductor element and a connection portion of the connection member with respect to the substrate, and exposes an entire front side of the semiconductor element that accepts connection of one end side of the connection member.
   (10)

The semiconductor device described in above (9) further includes a light-blocking film portion that is provided on a surface on a side of the transparent member facing the semiconductor element, covers an upper side of the connection portion of at least the connection member with respect to the semiconductor element, and restricts the intrusion of the resin material for forming the sealing resin portion into the inside of the transparent member.

(11)

In the semiconductor device described in above (9) or above (10), the transparent member includes a protrusion portion on a side facing the semiconductor element, the protrusion portion forming a second surface portion located on a side of the semiconductor element with respect to a first surface portion covered with the sealing resin portion.

(12)

In the semiconductor device described in any one of above (9) to (11), the transparent member includes a peripheral wall portion that forms a contact portion with respect to the sealing resin portion in a region on an outer side of the semiconductor element in plan view.

(13)

An electronic device includes a semiconductor device that includes:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, and the semiconductor element includes, on a front side, a resin restriction portion that restricts intrusion of a resin material for forming the sealing resin portion into an inside of the semiconductor element.
   (14)

An electronic device includes a semiconductor device that includes:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, and the sealing resin portion covers a side surface of the semiconductor element and a connection portion of the connection member with respect to the substrate, and exposes an entire front side of the semiconductor element that accepts connection of one end side of the connection member.
   (15)

A manufacturing method for a semiconductor device includes:
providing a semiconductor element on a substrate;
providing a connection member that electrically connects the substrate and the semiconductor element;
applying a sealing resin material around the semiconductor element on the substrate so as to cover at least a side surface of the semiconductor element and a connection portion of the connection member with respect to the substrate;
mounting, on the sealing resin material, a transparent member located above the semiconductor element; and
curing the sealing resin material.

### REFERENCE SIGNS LIST

1 Solid-state imaging device (semiconductor device)
2 Substrate
3 Image sensor (semiconductor element)
3a Front surface
4 Wire (connection member)
4c Exposed portion
5 Glass (transparent member)
5b Back surface
5c Side surface
5d Exposure surface portion
6 Sealing resin portion
8 Cavity
20 Resin restriction portion
21 Groove portion
31 Ridge portion
35 Step portion
35a Step surface
42 Glass groove portion (groove portion)
62 Resin film portion
92 Light-blocking film
125 Step portion
126 Step surface (first surface portion)
127 Protrusion surface portion
127b Lower surface (second surface portion)
135 Peripheral wall portion
136 Lower surface
137 Recess portion
138 Peripheral wall portion
200 Camera device (electronic device)
201 Solid-state imaging device (semiconductor device)

1. A semiconductor device comprising:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, wherein the semiconductor element includes, on a front side, a resin restriction portion that restricts intrusion of a resin material for forming the sealing resin portion into an inside of the semiconductor element.

2. The semiconductor device according to claim 1, wherein the resin restriction portion is one or a plurality of groove portions that are formed on the front side of the semiconductor element.

3. The semiconductor device according to claim 1, wherein the transparent member is a plate-like member whose one plate surface faces the semiconductor element, and has most of a portion on an upper side of a side surface as an exposed surface portion that is not covered with the sealing resin portion.

4. The semiconductor device according to claim 1, wherein the transparent member includes at least one of one or a plurality of groove portions and ridge portions on a surface on a side facing the semiconductor element, the groove portions and the ridge portions restricting the intrusion of the resin material for forming the sealing resin portion into the inside of the transparent member.

5. The semiconductor device according to claim 1, wherein
the transparent member includes a groove portion on a surface on a side facing the semiconductor element,
the connection member is a wire whose upper side is disposed as a protrusion side such that an upper end is located at a position higher than a front surface of the semiconductor element, and
the groove portion is formed in a region including at least part of a portion of the connection member existing at the position higher than the front surface of the semiconductor element in plan view.

6. The semiconductor device according to claim 1, further comprising a resin film portion that is provided on a surface of the transparent member on a side facing the semiconductor element, and restricts the intrusion of the resin material for forming the sealing resin portion into the inside of the transparent member.

7. The semiconductor device according to claim 6, wherein the resin film portion is formed as a light-blocking film.

8. The semiconductor device according to claim 1, wherein the semiconductor element includes a step portion as the resin restriction portion on the front side, the step portion forming a step formed at a periphery portion of the semiconductor element and on a side lower than an other portion of the semiconductor element, and forming a step surface that accepts connection of the connection member and is covered with the sealing resin portion.

9. A semiconductor device comprising:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, wherein the resin sealing resin portion covers a side surface of the semiconductor element and a connection portion of the connection member with respect to the substrate, and exposes an entire front side of the semiconductor element that accepts connection of one end side of the connection member.

10. The semiconductor device according to claim 9, further comprising a light-blocking film portion that is provided on a surface on a side of the transparent member facing the semiconductor element, covers an upper side of the connection portion of at least the connection member with respect to the semiconductor element, and restricts the intrusion of the resin material for forming the sealing resin portion into the inside of the transparent member.

11. The semiconductor device according to claim 9, wherein the transparent member includes a protrusion portion on a side facing the semiconductor element, the protrusion portion forming a second surface portion located on a side of the semiconductor element with respect to a first surface portion covered with the sealing resin portion.

12. The semiconductor device according to claim 9, wherein the transparent member includes a peripheral wall portion that forms a contact portion with respect to the sealing resin portion in a region on an outer side of the semiconductor element in plan view.

13. An electronic device comprising a semiconductor device that includes:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, wherein the semiconductor element includes, on a front side, a resin restriction portion that restricts intrusion of a resin material for forming the sealing resin portion into an inside of the semiconductor element.

14. An electronic device comprising a semiconductor device that includes:
a substrate;
a semiconductor element that is provided on the substrate;
a connection member that electrically connects the substrate and the semiconductor element;
a transparent member that is provided on an opposite side to a side of the substrate with respect to the semiconductor element; and
a sealing resin portion that supports the transparent member with respect to the substrate, seals surroundings between the substrate and the transparent member, and forms a cavity between the semiconductor element and the transparent member together with the semiconductor element and the transparent member, wherein the sealing resin portion covers a side surface of the semiconductor element and a connection portion of the connection member with respect to the substrate, and exposes an entire front side of the semiconductor element that accepts connection of one end side of the connection member.

15. A manufacturing method for a semiconductor device, the method comprising:
providing a semiconductor element on a substrate;
providing a connection member that electrically connects the substrate and the semiconductor element;
applying a sealing resin material around the semiconductor element on the substrate so as to cover at least a side surface of the semiconductor element and a connection portion of the connection member with respect to the substrate;
mounting, on the sealing resin material, a transparent member located above the semiconductor element; and
curing the sealing resin material.
